(19) United States
(12) Patent Application Publication
(10) Pub. No.: US 2026/0095065 A1
(43) Pub. Date: Apr. 2, 2026

(54) SYNCHRONIZATION METHOD FOR WIRELESS POWER TRANSFER SYSTEM BY DETECTING VOLTAGE TRANSIENT USING A SENSOR INDUCTOR

(71) Applicant: City University of Hong Kong, Kowloon (HK)

(72) Inventors: Xiaosheng Wang, Kowloon (HK); Chaoqiang Jiang, Kowloon (HK); Shuanling Wang, Wuhu City (CN); Liping Mo, Kowloon (HK)

(21) Appl. No.: 19/271,878

(22) Filed: Jul. 17, 2025

Related U.S. Application Data
(60) Provisional application No. 63/699,902, filed on Sep. 27, 2024.

(51) Int. Cl. H02J 50/12; H03H 7/01

(52) U.S. Cl. CPC H02J 50/12; H03H 7/0138

(57) ABSTRACT

A wireless power transfer (WPT) system with series-series compensation contains an inverter at a primary side, a rectifier at a secondary side, and a resonant circuit configured between the inverter and the rectifier. The resonant circuit includes a primary coil and a secondary coil. The resonant circuit further contains a sensor inductor connected to the secondary coil. The sensor inductor is adapted to detect voltage transients on the sensor inductor. By analyzing the voltage transients, the system can achieve frequency and phase synchronization between the inverter and rectifier, ensuring that both sides operate in harmony.

### FIELD OF INVENTION

This invention relates to wireless power transfer (WPT) systems, and in particular to frequency and/or phase synchronization between an inverter and a rectifier.

### BACKGROUND OF INVENTION

WPT can achieve safe and convenient energy transfer, which has got much focus in many applications [1]. The traditional structure is composed of an inverter, a rectifier, and a coupler. To achieve a high energy transfer efficiency in light load, some technologies like connecting a DC-DC converter with the uncontrolled rectifier [2] or using the active rectifier at the receiver side [3] are proposed. Compared with the WPT system with an uncontrolled rectifier, the one with an active rectifier can achieve higher efficiency without an additional DC-DC converter and even can easily achieve bidirectional power transfer [4].

To achieve continuous power regulation, dual-phase shift control [5] is usually used to optimize system efficiency by controlling the voltage ratio across the coupler. To further achieve zero voltage switching (ZVS), triple phase shift (TPS) is proposed [6]-[7], in which the phase shift of the inverter and rectifier and their voltage phase difference are controlled to optimize the system efficiency and the ZVS operation. In these typical control methods for the WPT system with the active rectifier, the phase synchronization between the inverter and the rectifier is necessary.

Time delays of communication techniques such as Wi-Fi, usually last several milliseconds, making it difficult to achieve synchronization between both sides. Additionally, the high-power operation of the WPT system may affect the reliability of wireless devices due to electromagnetic interference [8]. Therefore, the synchronization method independent of real-time communication techniques attracts much attention.

According to the existing literature, the synchronization method can be classified into two main classes. The first one is using the zero-crossing detection (ZCD) circuit on the secondary side to convert the frequency and phase information of the inverter to the driving pulses of the rectifier. In [9], an additional coil is placed on the receiver coil to detect the current flowing out the inverter by using another compensation sensor to decouple the effect of receiver-side current, and then the synchronization can be achieved by using ZCD on the receiver. However, the decoupling can be affected by the coil misalignment. Moreover, the synchronization can be affected by the system detuning. In [10], the synchronization is implemented by using a counter to track the zero-crossing point of the current flowing into the rectifier, which is based on the condition that the rectifier current lags the inverter output voltage by 90°. Hence, the synchronization method is also sensitive to the system detuning because the condition will be affected if the system is detuned. Similar synchronization techniques based on the ZCD are also presented in [11]-[13]. The effect of harmonics on synchronization is analyzed, especially for LCC-LCC topology, where multiple zero-crossing points may exist. In [14], a similar method based on the ZCD circuit is applied to the bidirectional capacitive power transfer systems.

Another common method is detecting and processing current flowing into the rectifier. In [15], two mutually orthogonal five-level square waves are designed to eliminate odd-numbered harmonics, which are multiplied by the sampled current to calculate and control the angle between the rectifier voltage and current to achieve synchronization. This method can reduce the effect of current harmonics. However, the method is also sensitive to system detuning. In [8], the relationship between the output power and the voltage phase difference of the inverter and rectifier is presented. Controlling the output power at the maximum value can achieve a 90° phase difference between the voltages on both sides. However, it cannot achieve arbitrary phase differences, which is not suitable for the TPS control [7]. In addition, detuning can also affect the performance. In [16], to achieve synchronization, the reactive component of the secondary side current should be sampled and controlled to 0. In [17], the power fluctuation phenomenon caused by different switching frequencies on both sides is presented. By controlling the output active power without fluctuation, the frequency synchronization on both sides can be achieved. However, arbitrary phase differences cannot be implemented for these methods. In [18], the rectifier voltage is multiplied by the secondary current and the 900 phase-shifted secondary current, respectively, and then the phase difference between the voltages of the inverter and rectifier is obtained. However, the harmonics in the voltage and current will affect the synchronization result.

In addition, in [19] and [20], the voltage across the secondary compensation capacitor is used for frequency tracking, and the maximum output dc voltage is used for phase synchronization. However, for the battery load, detecting the maximum output dc voltage is not feasible. In [21], an additional inverter and a set of coils are added. The phase difference between the voltages of the inverter and the rectifier can be reflected by the voltage of the new receiving coil. However, many new components should be added, and the new coils should be designed to be large to overcome the effect of the misalignment, which seriously limits the practicality of this solution.

### REFERENCES

All referenced literatures throughout this disclosure are incorporated herein by reference in their entirety, which include the following references:
[1]Z. Zhang, H. Pang, A. Georgiadis and C. Cecati, “Wireless Power Transfer—An Overview,” IEEE Trans. Ind. Electron, vol. 66, no. 2, pp. 1044-1058, February 2019.
[2]M. Fu, C. Ma and X. Zhu, “A Cascaded Boost-Buck Converter for High-Efficiency Wireless Power Transfer Systems,” IEEE Trans. Ind. Informat, vol. 10, no. 3, pp. 1972-1980, August 2014.
[3]Y. Zhang, X. Li, S. Chen and Y. Tang, “Soft Switching for Strongly Coupled Wireless Power Transfer System With 90° Dual-Side Phase Shift,” IEEE Trans. Ind. Electron, vol. 69, no. 1, pp. 282-292, January 2022.
[4]U. K. Madawala and D. J. Thrimawithana, “A Bidirectional Inductive Power Interface for Electric Vehicles in V2G Systems,” IEEE Trans. Ind. Electron, vol. 58, no. 10, pp. 4789-4796, October 2011.
[5]Y. Li, J. Hu, F. Chen, Z. Li, Z. He and R. Mai, “Dual-Phase-Shift Control Scheme With Current-Stress and Efficiency Optimization for Wireless Power Transfer Systems,” IEEE Trans. Circuits Syst. I, Reg. Papers, vol. 65, no. 9, pp. 3110-3121, September 2018.
[6]X. Zhang et al., “A Control Strategy for Efficiency Optimization and Wide ZVS Operation Range in Bidirectional Inductive Power Transfer System,” IEEE Trans. Ind. Electron, vol. 66, no. 8, pp. 5958-5969, August 2019.
[7]S. Jia, C. Chen, S. Duan and Z. Chao, “Dual-Side Asymmetrical Voltage-Cancelation Control for Bidirectional Inductive Power Transfer Systems,” IEEE Trans. Ind. Electron, vol. 68, no. 9, pp. 8061-8071, September 2021.
[8]F. Liu, K. Li, K. Chen and Z. Zhao, “A Phase Synchronization Technique Based on Perturbation and Observation for Bidirectional Wireless Power Transfer System,” IEEE Trans. Emerg. Sel. Topics Power Electron, vol. 8, no. 2, pp. 1287-1297, June 2020.
[9]D. J. Thrimawithana, U. K. Madawala and M. Neath, “A Synchronization Technique for Bidirectional IPT Systems,” IEEE Trans. Ind. Electron, vol. 60, no. 1, pp. 301-309, January 2013.
[10]S. Jia, C. Chen, P. Liu and S. Duan, “A Digital Phase Synchronization Method for Bidirectional Inductive Power Transfer,” IEEE Trans. Ind. Electron, vol. 67, no. 8, pp. 6450-6460, August 2020.
[11]D. Zhang, M. Chen, B. Li, X. Wang, X. Sun and F. Jiang, “Synchronization Strategy Based on Resonant Current Detection for Bidirectional Wireless Charging System,” IEEE Trans. Power Electron, vol. 37, no. 9, pp. 11436-11449, September 2022.
[12]H. Li, L. Tan, H. Qi, X. Li, Z. Wu and X. Huang, “Research on Secondary-Side Synchronization Method of Wireless Power Transfer Systems,” IECON 2023-49th Annual Conference of the IEEE Industrial Electronics Society, Singapore, Singapore, 2023, pp. 1-6.
[13]Z. Huang, B. Zou, Z. Huang, H. H.-C. Iu, and C. K. Tse, “A single-stage IPT converter with optimal efficiency tracking and constant voltage output against dynamic variations of coupling and load,” IEEE Trans. Transport. Electrific., early access, May 2024, doi: 10.1109/TTE.2024.3407717.
[14]M. Sun, X. Dai, Y. Su, Y. Li and S. Zhao, “Frequency and Phase Synchronous Control Method Without Communication of the BCPT System,” IEEE Trans. Power Electron, vol. 39, no. 4, pp. 4792-4804, April 2024.
[15]S. Jia, S. Duan and C. Chen, “An I/Q Phase Detection-Based Harmonic-Insensitive Phase Synchronization Method for Bidirectional Wireless Power Transfer System,” IEEE Trans. Ind. Electron, doi: 10.1109/TIE.2023.3314918.
[16]S. Zhao, Y. Li, D. Wu and R. Mai, “Current-Decomposition-Based Digital Phase Synchronization Method for BWPT System,” IEEE Trans. Power Electron, vol. 36, no. 11, pp. 12183-12188, November 2021.
[17]D. J. Thrimawithana, U. K. Madawala and M. Neath, “A P&Q based synchronization technique for Bidirectional IPT pick-ups,” 2011 IEEE Ninth International Conference on Power Electronics and Drive Systems, Singapore, 2011, pp. 40-45.
[18]Y. Tang, Y. Chen, U. K. Madawala, D. J. Thrimawithana and H. Ma, “A New Controller for Bidirectional Wireless Power Transfer Systems,” IEEE Trans. Power Electron, vol. 33, no. 10, pp. 9076-9087, October 2018.
[19]X. Liu, N. Jin, D. Ma and X. Yang, “A Simple and Effective Synchronization Technique for Wireless Power Transfer System,” 2018 IEEE Wireless Power Transfer Conference (WPTC), Montreal, QC, Canada, 2018, pp. 1-4.
[20]X. Liu, N. Jin, X. Yang and T Wang. “A novel synchronization technique for wireless power transfer systems,” Electronics, 2018, 7(11): 319.
[21]Y. Zhang, S. Chen, X. Li and Y. Tang, “Dual-Side Phase-Shift Control of Wireless Power Transfer Implemented on Primary Side Based on Driving Windings,” IEEE Trans. Ind. Electron, vol. 68, no. 9, pp. 8999-9002, September 2021.
[22]A. Safaee and K. Woronowicz, “Time-Domain Analysis of Voltage-Driven Series-Series Compensated Inductive Power Transfer Topology,” IEEE Trans. Power Electron, vol. 32, no. 7, pp. 4981-5003, July 2017.
[23]B. Carter, “High-speed notch filters,” Analog Appl. J., vol. Q1, pp. 8, 2006.
[24]Y. Jiang, L. Wang, Y. Wang, J. Liu, M. Wu and G. Ning, “Analysis, Design, and Implementation of WPT System for EV's Battery Charging Based on Optimal Operation Frequency Range,” IEEE Trans. Power Electron., vol. 34, no. 7, pp. 6890-6905, July 2019.
[25]J. Liu, G. Wang, G. Xu, J. Peng, and H. Jiang, “A parameter identification approach with primary-side measurement for DC-DC wireless-power-transfer converters with different resonant tank topologies,” IEEE Trans. Transp. Electrific., vol. 7, no. 3, pp. 1219-1235, September 2021.

### SUMMARY OF INVENTION

Accordingly, in a first aspect of the invention there is provided a WPT system with a series compensation structure on a primary side. The system contains an inverter at the primary side, a rectifier at a secondary side, and a resonant circuit configured between the inverter and the rectifier; the resonant circuit comprising a primary coil and a secondary coil. The resonant circuit further contains a sensor inductor connected to the secondary coil; the sensor inductor adapted to detect voltage transients on the sensor inductor.

In some embodiments, the sensor inductor is connected to the secondary coil in series.

In some embodiments, the sensor inductor is connected to a different terminal of the secondary coil than a capacitor at the secondary side which is also connected to the secondary coil.

In some embodiments, the sensor inductor includes a magnetic ring.

In some embodiments, the magnetic ring is wound with a multiturn coil.

In some embodiments, the magnetic ring is a nickel-zinc magnetic ring.

In some embodiments, the magnetic ring has a magnetic permeability of 100.

In some embodiments, the magnetic ring has a number of coil turns equal to 22.

In some embodiments, the rectifier is an active rectifier containing a plurality of transistors. The sensor inductor is further coupled with a sampling circuit, which in turn connects to a driving circuit; the driving circuit adapted to provide driving signals to the rectifier based on the detected voltage transients by the sensor inductor.

In some embodiments, the sensor inductor is connected to a filter, which in turn connects to the sampling circuit.

In some embodiments, the filter is a notch filter or a high-pass filter.

According to another aspect of the invention, there is provided a method for phase synchronization between a primary side and a secondary side of a WPT system with a series compensation structure. The WPT system contains an inverter at the primary side and an active rectifier at the secondary side. The method includes steps of; detecting, at the secondary side, voltage transients by a sensor inductor; sampling the detected voltage transients; and controlling an operation of the active rectifier based on the detected voltage transients.

In some embodiments, the method further includes a step of filtering the detected voltage transients from the sensor inductor by a filter.

In some embodiments, the filter is a notch filter or a high-pass filter.

In some embodiments, the sensor inductor includes a magnetic ring.

In some embodiments, the magnetic ring is wound with a multiturn coil.

In some embodiments, the magnetic ring is a nickel-zinc magnetic ring.

In some embodiments, the magnetic ring has a magnetic permeability of 100.

In some embodiments, the magnetic ring has a number of coil turns equal to 22.

Exemplary embodiments of the invention therefore provide circuit structures and synchronization method for WPT systems which utilize an equivalent sensor inductor, implemented for example as a magnetic ring with multiple coil turns, connected in series to the resonant tank on the secondary (receiver) side. This sensor inductor is pivotal for detecting voltage transients caused by sudden changes in the inverter's output voltage. The method employs a notch filter to accentuate the transient features detected by the sensor inductor. By analyzing these voltage transients, the system can achieve frequency and phase synchronization between the inverter and rectifier, ensuring that both sides operate in harmony. This synchronization process is robust against system detuning and is adaptable to various operating frequencies, making it highly versatile.

### BRIEF DESCRIPTION OF FIGURES

The foregoing and further features of the present invention will be apparent from the following description of embodiments which are provided by way of example only in connection with the accompanying figures, of which:

FIG. 1 shows the typical structure of a Series-Series (S-S) compensated WPT system with an active rectifier.

FIG. 2 illustrates voltage and current waveforms of the WPT system in FIG. 1 under TPS control.

FIG. 3 illustrates a T-shaped equivalent circuit of the WPT system in FIG. 1. (a) T-shaped equivalent circuit. (b) if only voltage transient time is considered.

FIG. 4 illustrates the relationship between the voltage transient on the sensor inductor and the coupling coefficient k (Vᵢₙ=Vₒ=100 V, L₁=L₂=100 μH, Ls=2 μH).

FIG. 5 shows voltage and current waveforms of the WPT system in FIG. 1 under TPS control (Vᵢₙ=Vₒ=100 V, L₁=L₂=100 μH, Ls=2 μH, fₛ=fᵣ=85 kHz, α=α/2, β=2π/3, θ=π/4). (a) k=0.2. (b) k=0.5.

FIG. 6 shows the voltage transient enhancement results crossing a notch filter (ω=85*2π kHz). (a) Waveform of u_{Ls}. (b) Waveform of u_{Lse} crossing a notch filter (gₘᵢₙ=0.01, ζ=0.588).

FIG. 7 shows the voltage transient enhancement results crossing the high-pass filter. (a) Waveform of u_{Ls}. (b) Waveform of u_{Lse} crossing a first-order Butterworth high-pass filter (cutoff frequency is 1 MHz). (c) Waveform of u_{Lse} crossing a third-order Butterworth high-pass filter (cutoff frequency is 1 MHz).

FIG. 8 shows implementation of the synchronization method for the ideal situation. (a) inverter output voltage and current. (b) rectifier input voltage and current. (c) the voltage of the sensor inductor after crossing the notch filter. (d) transient detection signal P_{S}. (e) counters for inverter and rectifier. (f) generating rectifier driving signals.

FIG. 9 illustrates the synchronization methods when the voltage transient moments of u_{P} and u_{S} coincide. (a) Four moments coincide during one switching period. (b) Two moments coincide during one switching period (case 1). (c) Two moments coincide during one switching period (case 2). (d) Two moments coincide during one switching period (case 3). (e) Two moments coincide during one switching period (case 4).

FIG. 10 shows a circuit structure for conducting a synchronization method according to an embodiment of the invention.

FIG. 11 illustrates methods for detecting voltage transient points. (a) Ideal waveform and actual waveform of u_{Ls}. (c) Methods for detecting voltage transient points.

FIG. 12 shows a compensation scheme for time delays introduced by hardware and sampling.

FIG. 13a displays waveforms of the voltages and currents when α=β=180°, θ=90°, c=10.

FIG. 13b displays waveforms of the voltages and currents when α=β=180°, θ=90°, μᵣ=100.

FIG. 13c displays waveforms of the voltages and currents when α=β=180°, θ=90°, μᵣ=700.

FIG. 13d is a temperature diagram of magnetic ring after running for 10 min with 4 A.

FIG. 14a displays waveforms of the voltages and currents when α=β=180°, θ=90°, fₛ=85 kHz.

FIG. 14b displays waveforms of the voltages and currents when α=β=180°, θ=90°, fₛ=90 kHz.

FIG. 14c illustrates a dynamic waveform when fₛ changes from 85 kHz to 90 kHz.

FIG. 14d is an enlarged view of FIG. 14c.

FIG. 15a displays waveforms of the voltages and currents when α=β=150°, fₛ=85 kHz, θ=90°.

FIG. 15b displays waveforms of the voltages and currents when α=β=150°, fₛ=85 kHz, θ=70°.

FIG. 15c is a dynamic waveform when θ changes from 900 to 70°.

FIG. 15d is an enlarged view of FIG. 15c.

FIG. 16a displays waveforms of the voltages and currents when α=β=150°, θ=90°, fₛ=90 kHz.

FIG. 16b displays waveforms of the voltages and currents when α=β=150°, θ=90°, fₛ=80 kHz.

FIG. 16c a displays dynamic waveform when fₛ changes from 90 to 80 kHz.

FIG. 16d is an enlarged view of FIG. 16c.

FIG. 17a displays waveforms of the voltages and currents when α=180°, β=90°, θ=90°, fₛ=85 kHz.

FIG. 17b displays waveforms of the voltages and currents when α=β=150°, θ=90°, fₛ=80 kHz.

FIG. 17c displays a dynamic waveform when fₛ changes from 85 to 80 kHz.

FIG. 17d is an enlarged view of FIG. 17c.

FIG. 18a displays waveforms of the voltages and currents when β=180°, θ=90°, fₛ=85 kHz, α=180°.

FIG. 18b displays waveforms of the voltages and currents when β=180°, θ=90°, fₛ=85 kHz, α=135°.

FIG. 18c illustrates a dynamic waveform when a changes from 1800 to 135°.

FIG. 18d is an enlarged view of FIG. 18c.

FIG. 19a displays waveforms of the voltages and currents when α=β=180°, fₛ=85 kHz, and θ=900 under loose coupling case (k=0.13).

FIG. 19b displays waveforms of the voltages and currents when α=β=180°, fₛ=85 kHz, and θ=700 under loose coupling case (k=0.13).

FIG. 19c illustrates a dynamic waveform when fₛ changes from 90° to 70°.

FIG. 19d illustrates an enlarged view of FIG. 19c.

FIG. 20 shows a typical structure of a S-P compensated WPT system.

FIG. 21 shows the voltage and current waveforms of the S-P compensated WPT system (Vᵢₙ=100 V, L₁=L₂=100 μH, C₁=40 nF, C₂=35 nF, k=0.4, Rₒ=100Ω).

### DETAILED DESCRIPTION OF PREFERRED EMBODIMENTS

In the claims which follow and in the preceding description, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

As used herein and in the claims, “couple” or “connect” refers to electrical coupling or connection either directly or indirectly via one or more electrical means unless otherwise stated.

For the Series-Series (S-S) compensated WPT systems, the inverter's output voltage has a sudden change when the switches are turned on or off, and this sudden change will pass through the coupler and further affect the secondary current. In an embodiment of the invention, an equivalent sensor inductor (for example, a magnetic ring with multiple turns of wire) is added to the secondary side to detect sudden changes in voltage. By detecting the voltage transient on the sensor and controlling the driving signals of the active rectifier, synchronization can be achieved. The descriptions below begin by analyzing the principle of system synchronization based on voltage transients and then examines the relationship between the extent of voltage transients and the coupling coefficient. Finally, a synchronization strategy entirely unaffected by system detuning and current harmonics according to an embodiment of the invention is proposed, which doesn't have complex mathematical computations and current sensors, facilitating deployment. The performance of the proposed method in the embodiment is validated through experiments.

The S-S compensation and doubled-sided LCC (LCC-LCC) compensation are commonly used in the WPT system. The proposed synchronization method is applicable to the SS structure but not suitable for the LCC-LCC structure. The reason is that the parallel capacitor in this LCC compensator prevents the inverter's voltage transient from being transmitted to the receiver due to the filtering effect of the capacitor. Consequently, the S-S compensated WPT system is studied.

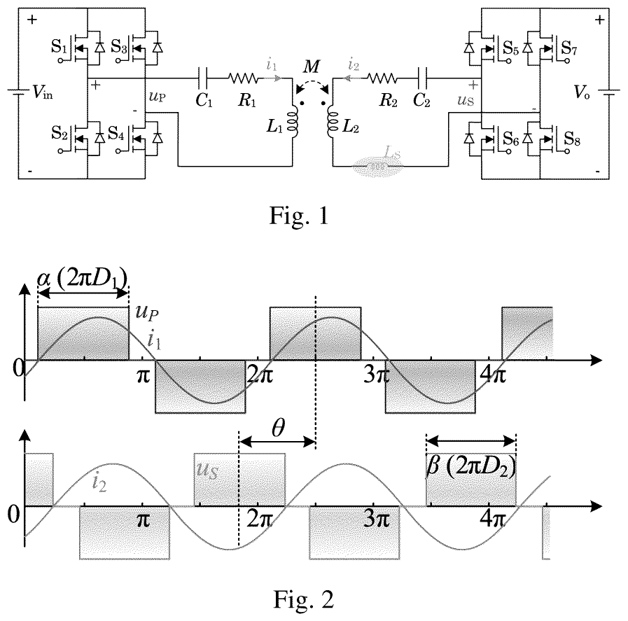

FIG. 1 presents the typical structure of an S-S compensated WPT system. Sₓ are the power switches of the primary-side inverter and the secondary-side rectifier, respectively. The DC voltages of the primary and secondary sides are represented by Vᵢₙ and Vₒ. u_{P} and u_{S} are the output voltage of the primary-side inverter and the input voltage of the secondary-side rectifier. L₁-L₂, C₁-C₂, and R₁-R₂ are the dual-side resonant inductance, capacitance, and AC equivalent parasitic resistance of the resonant tank and power switches. M is the mutual inductance.

FIG. 2 presents the ideal waveform of the WPT system under TPS control [6], [7] with only the fundamental component considered. D₁ and D₂ are the duty cycle of u_{P} and u_{S}, θ is the phase shift between the fundamental components of u_{P} and u_{S}. Regulating the three parameters can achieve the ZVS of the inverter and rectifier. Since the TPS strategy is a very typical application of phase synchronization, where θ can be an arbitrary value. To verify the generality of the proposed method, the phase synchronization method will be analyzed for the TPS control of the WPT system.

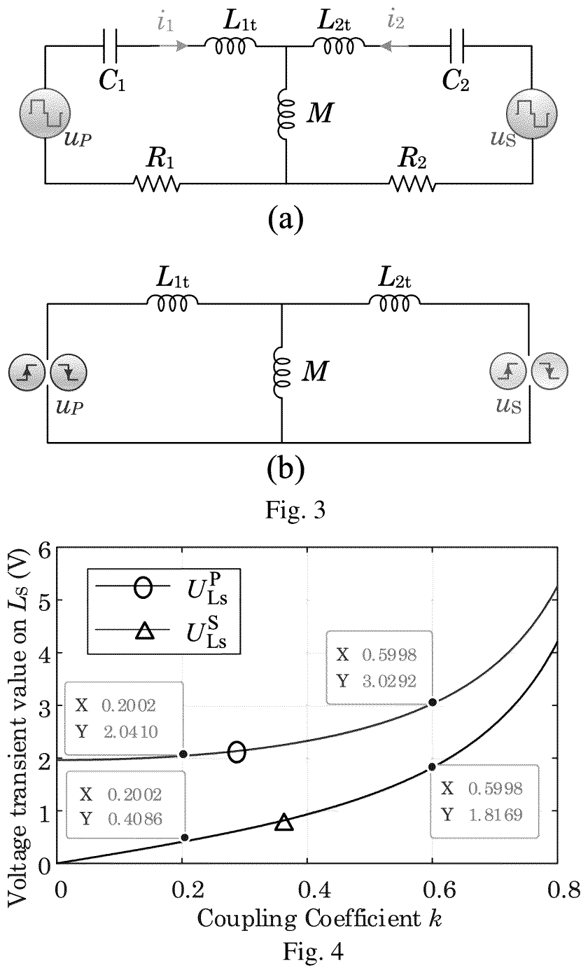

The typical structure shown in FIG. 1 can be converted to a T-shaped equivalent circuit shown in FIG. 3(a), where the inverter and rectifier are simplified to two square wave voltage sources. L₁ₜ and L₂ₜ can be represented by:

$$\{ \begin{matrix}{L}_{1 t} = {L}_{1} - M \\ {L}_{2 t} = {L}_{2} - M\end{matrix} \qquad ( 1 )$$

When discussing the voltage transient of the WPT system, the time domain analysis method shown in [3], [22] can be used to obtain a steady state expression. After obtaining the time domain expression of i₁ and i₂, the voltage expressions of different components can be also solved. However, since multiple switching moments decompose the system into multiple states, solving the time domain expression over the entire time will become complicated. Moreover, the time domain analysis method cannot solve the dynamic expression when the WPT system starts up. To solve the voltage transient simply and effectively, a simplified model is presented here, which can always represent voltage transients including startup and other transient processes.

Since the rising time and falling time of u_{P} and u_{S} is only about dozens of nanoseconds, when discussing the voltage transient across the inductors L₁ₜ and L₂ₜ, the power supply can be viewed as a step excitation as shown in FIG. 3(b). Considering the voltage of C₁ and C₂ will not change suddenly during the short time, it can be further ignored.

In FIG. 3, when u_{P} rises from 0 to Vᵢₙ, the voltage transient value on the inductor L₂ₜ can be expressed as:

$${U}_{{L}_{2 t}}^{P} = {V}_{i n} \frac{M {L}_{2 t}}{{L}_{1 t} ( M + {L}_{2 t} ) + M {L}_{2 t}} \qquad ( 2 )$$

When u_{S} rises from 0 to Vₒ, the voltage transient value on the inductor L₂ₜ can be expressed as:

$${U}_{{L}_{2 t}}^{S} = {V}_{o} \frac{{L}_{2 t} ( M + {L}_{1 t} )}{{L}_{2 t} ( M + {L}_{1 t} ) + M {L}_{1 t}} \qquad ( 3 )$$

Based on the above analysis, if the voltage on the L₂ₜ can be detected, then the switching moments of the inverter and rectifier can be perceived. The phase synchronization can be implemented according to the voltage transient phenomenon. However, in practice, the L₂ₜ is coupled to M, only the voltage across L₂ can be measured, which will not change suddenly when u_{P} and u_{S} rise or fall suddenly. To detect the voltage transient, an additional small sensor inductor L_{S} is designed to be connected in series with coil L₂ as shown in FIG. 1. The voltage transient on the sensor inductor L_{S} can be represented by:

$$\{ \begin{matrix}{U}_{{L}_{S}}^{S} = {V}_{o} \frac{{L}_{2 t}^{′} ( M + {L}_{1 t} )}{{L}_{2 t}^{′} ( M + {L}_{1 t} ) + M {L}_{1 t}} \frac{{L}_{S}}{{L}_{2 t}^{′}} \\ {U}_{{L}_{S}}^{P} = {V}_{i n} \frac{M {L}_{2 t}^{′}}{{L}_{1 t} ( M + {L}_{2 t}^{′} ) + M {L}_{1 t}} \frac{{L}_{S}}{{L}_{2 t}^{′}}\end{matrix} \qquad ( 4 )$$

$$where$$

$${L}_{2 t}^{′} = {L}_{2 t} + {L}_{S} .$$

It can be found that the voltage transient on the sensor inductor L_{S} will be affected by the mutual inductance or the coupling coefficient k, where k is:

$$k = \frac{M}{\sqrt{{L}_{1} {L}_{2}}} \qquad ( 5 )$$

FIG. 4 presents the voltage transient value under different coupling coefficients. With the increase of the coupling coefficient, the voltage transient phenomenon will be more obvious. The voltage transient value caused by the rising and falling of u_{S} is larger than that of u_{P}.

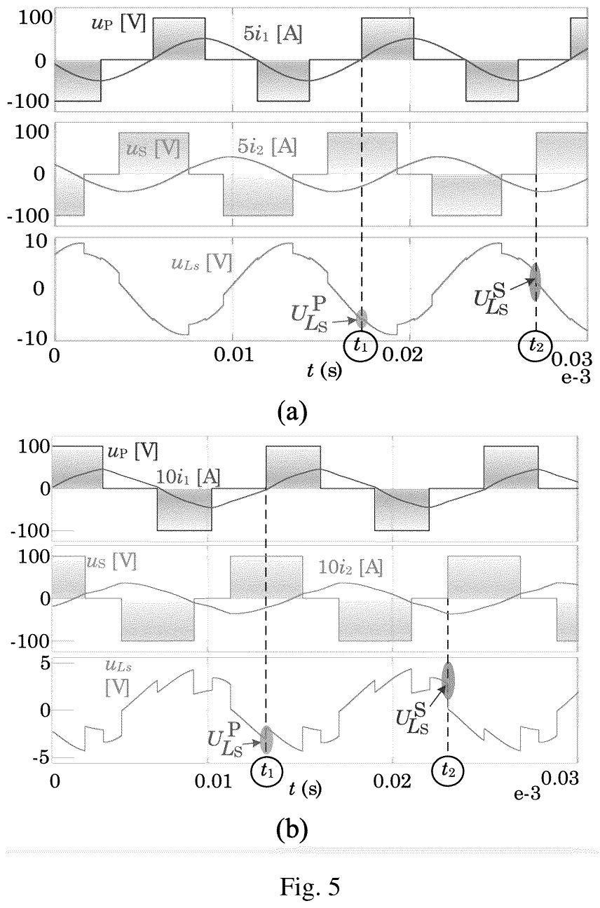

FIG. 5 presents the voltage and current waveforms of the WPT system under TPS control when switching frequency fₛ equal to the resonant frequency fᵣ of the resonant tank on both sides. As shown in FIG. 4, for weak coupling cases such as k=0.2, the voltage transient is not obvious. At moment t₁, the voltage transient value is only about 0.409 V. For the strong coupling case, it is very easy to detect the voltage transient phenomenon as shown in u_{Ls} in FIG. 5(b).

Consequently, the switching moments can be perceived by the receiver by measuring the voltage of the sensor inductor L_{S}. The phase synchronization can be further implemented by designing a driving strategy for the active rectifier.

As shown in FIG. 4 and FIG. 5, the voltage transient value caused by the rising and falling of u_{P} is very small for loose coupling cases. Considering that the fundamental amplitude of u_{LS} is far greater than the voltage transient value, it is difficult to perceive the transient time. To enhance the transient phenomenon, the filter is used to eliminate the fundamental component and keep the high-frequency components of u_{Ls}, which makes it easier to sense the voltage transient. For the filters, both high-pass filter and notch filter can be applied.

The primary characteristics of a notch filter include the notch frequency, bandwidth (or damping ratio ξ), and notch depth (or minimum attenuation gₘᵢₙ) [23]. The purpose of employing a notch filter is to eliminate the fundamental frequency component of u_{Ls}, and then to highlight the voltage transients. Consequently, the notch frequency should be set around the switching frequency. When the fundamental component of u_{Ls} is attenuated to 5% (notch depth is about −26 dB) of its original value through the notch filter, the transient enhancement effect is obvious. Considering the operating frequency of the WPT system can be 81.39-90 kHz according to the SAE J2954 standard when some frequency control schemes are adopted [24], to have a satisfying transient enhancement effect, the bandwidth of the notch filter should be wide so that there is enough notch depth in the potential operating frequency range. Fortunately, wide bandwidth and less demanding notch depth mean easier design.

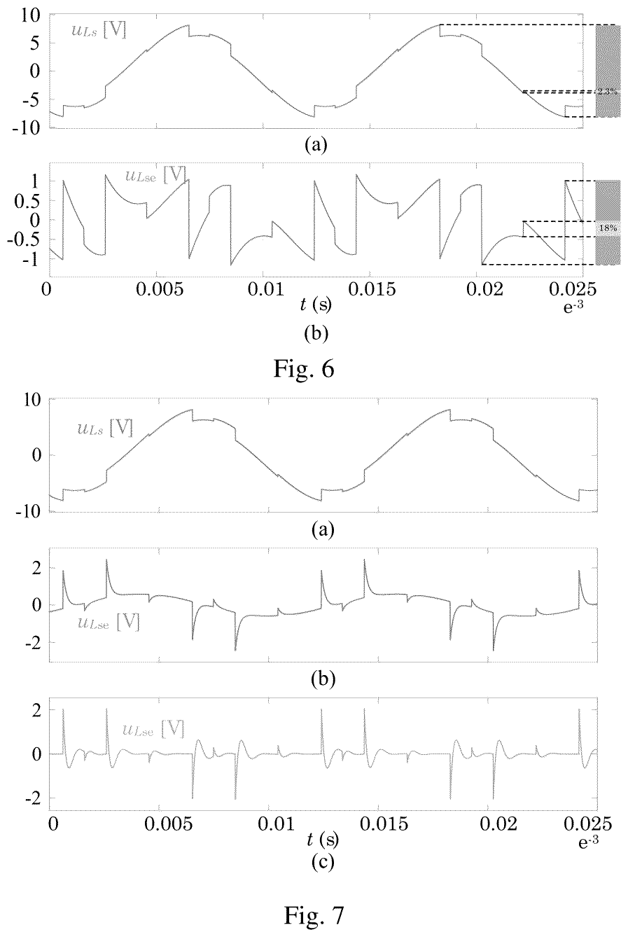

FIG. 6 presents the voltage transient enhancement results. As illustrated in FIG. 6(a), the transient feature caused by the rising and falling edges of u_{P} is not obvious, accounting for only approximately 2.5% of the peak-to-peak value. However, after passing through the notch filter, the transient feature is significantly enhanced, occupying around 18%. Similarly, FIG. 6(c) shows the filtered u_{Lse} signal after applying a high-pass filter, which also exhibits a notable enhancement of the transient feature. Therefore, both high-pass filters and notch filters can be employed to amplify transient features. Given the similarity in analysis and processing methods between the two filters, in this embodiment only the notch filter will be described.

When designing a high-pass filter, key parameters to consider are the cutoff frequency and the order of the filter. The filter order determines the steepness of the filter's frequency response curve. Higher order filters typically exhibit sharper attenuation characteristics, which are crucial for achieving effective low-frequency attenuation at lower cutoff frequencies. However, higher order filters may introduce oscillations for the signal transients as shown in FIG. 7(c), potentially interfering with the accurate detection of transient points and leading to misjudgments. Therefore, in practical applications, it is advisable to use the first-order high-pass filter to mitigate the effects of oscillations. To effectively reduce the fundamental component, the cut-off frequency of the high-pass filter is suggested to be set above 1 MHz. Considering that real signal transients often involve a slow rise or fall process, higher cutoff frequencies not only attenuate the fundamental signal but also diminish the amplitude of signal transients to a certain extent. Hence, the effect of transient enhancement with higher cutoff frequencies is limited.

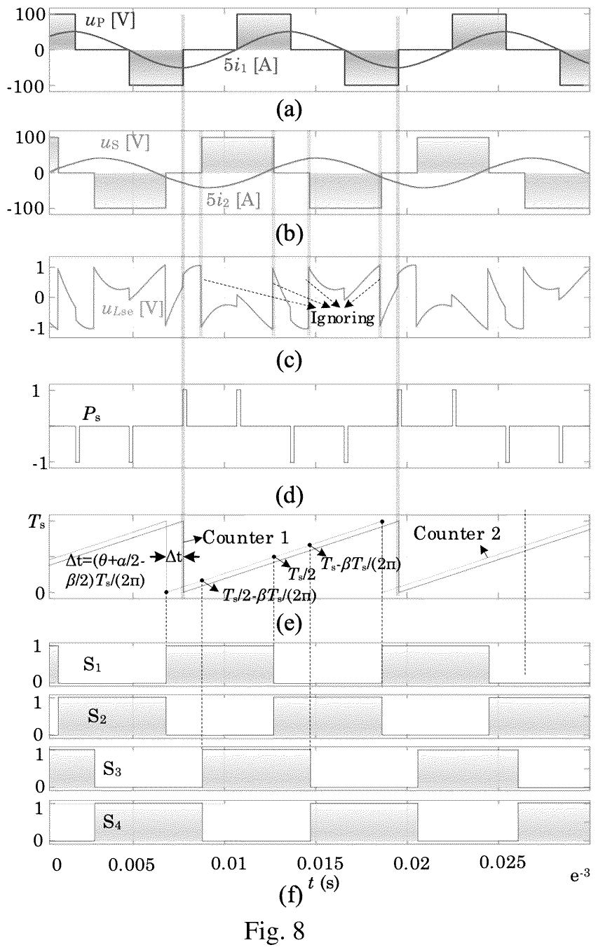

By detecting the voltage transient points of u_{Lse}, the voltage information in the primary inverter can be determined if the voltage transient points caused by the voltage changes of u_{S} are ignored. As shown in FIG. 8, the rising edge of the output voltage u_{P} of the primary inverter corresponds to a rising edge on u_{Lse}, and similarly, the falling edge corresponds to a falling edge on u_{Lse}. Conversely, the voltage transients on u_{Lse} caused by the secondary rectifier are opposite to those of the inverter. Since the synchronization strategy is implemented on the secondary side, the moments of rising and falling edges of the u_{S}, are known to the controller at the receiver end. A short time window is set at the moments of u_{S} changes, which should be sufficiently long to cover the rise time. During this time window, the voltage transients in the sensor inductor are disregarded, generating the transient detection signal P_{S} as shown in FIG. 8(d). P_{S} contains two positive and two negative pulses, each indicating the positions of voltage transients in u_{P}. Upon detecting the first rising edge following a falling edge, counter 1 is reset. When the first rising edge following the subsequent falling edge is detected again, the counter value is recorded and saved as Tₛ, representing the switching period. The switching sequence of the rectifier is determined based on the count value of counter 2. According to the angle definition of the TPS control, as shown in FIG. 2, counter 2 is formed by delaying counter 1 for Tₛ−Δt. The expression of Δt is shown in FIG. 8(e), where the α can be sensed by the rectifier by measuring the time interval between the two adjacent rising and falling transient points in u_{Lse}. The value of counter 2 corresponds to the moment when the u_{S} changes is also marked. According to the typical phase shift control, the driving signals corresponding to switches S1-S4 can be further obtained as shown in FIG. 8(f).

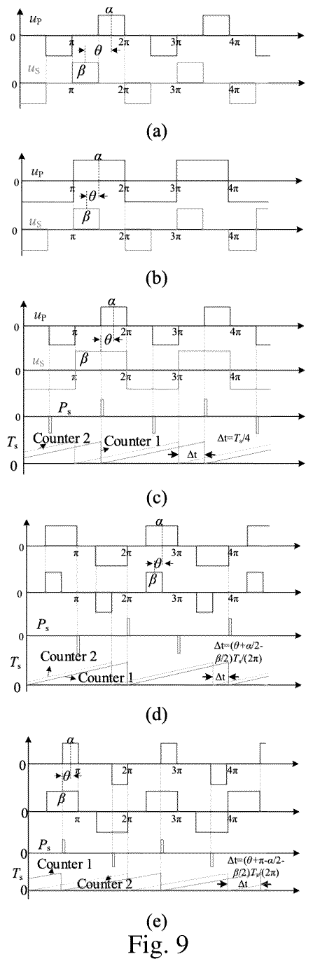

Although FIG. 8 presents the most common waveform for the TPS control. However, for some special cases, the transient moment of the u_{P} may be very close to or even coincide with the transient moment of the u_{S}. Since a short time window is set at the moments of u_{S} changes to cover its rise time. If the transient time of u_{P} and u_{S} is close, it is easy to ignore the transient information of u_{P}. As shown in FIG. 9, several examples of u_{S} and u_{P} transient points coincide are presented. During one switching period, the transient points may overlap in four moments or two moments due to the symmetry of the voltage waveform. FIG. 9(a) presents the situation when the four voltage transient moments of u_{P} and u_{S} coincide. However, considering that the θ is usually slightly smaller than α/2 and β/2 to obtain ZVS and high efficiency, the situation in FIG. 9(a) will rarely occur. In FIG. 9(b), α=71, β=π/2, θ=π/4, the transient points of u_{S} will cover all the transient points of u_{P}. This situation is suggested to be avoided when designing. For the situations shown in FIG. 9(c)-FIG. 9(e), the synchronization method is similar to that of FIG. 8. Upon detecting the first rising edge following a falling edge on u_{Lse}, counter1 is reset. When the first rising edge following the subsequent falling edge is detected again, the counter value is recorded and saved as Tₛ, representing the switching period. The time delay Tₛ−Δt between counters 1 and 2 should be regulated.

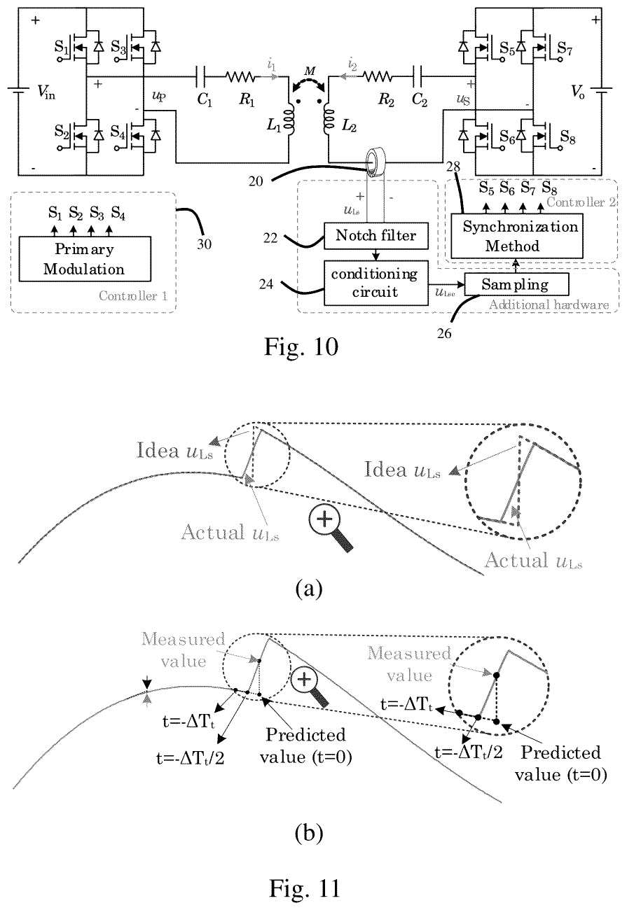

Connect the sensor inductor Lₛ in series to the resonant tank on the secondary side and detect the voltage on Lₛ can achieve synchronization. However, the detection circuit needs to be electrically isolated from the main circuit. Although some isolation chips can be used to achieve this purpose, there is a more attractive solution. FIG. 10 shows, in an exemplary embodiment, a small magnetic ring 20 inserted into the connection wire between the receiving coil L₂ and the rectifier. A multiturn coil is wound around the magnetic ring 20. The synchronization can also be achieved by detecting the voltage of the multiturn coil. The magnetic ring 20 can be regarded as a voltage transformer, a primary side of which has only one turn of coil and is connected in series between the receiving coil L₂ and the rectifier. Using a nickel-zinc magnetic ring with low magnetic permeability can ensure that the equivalent series inductance Lₛ has a small value. The additional power loss introduced on the magnetic ring can be ignored. Due to the parasitic capacitance Cp of the multiturn wire, a damping resistor R_{d} with a large resistance in parallel can effectively suppress the oscillation when the voltage on u_{Lse} changes suddenly.

FIG. 10 shows that the magnetic ring 20 is connected to a notch filter 22, which is in turn connected to a conditioning circuit 24, the latter in turn connected to a sampling circuit 26 It should be noted that the notch filter 22, the conditioning circuit 24 and the sampling circuit 26 are not part of the rectifier in the WPT system. Output of the sampling circuit 26 is provided to a second controller 28 that is adapted to drive the transistors S₅-S₈ in the rectifier. A first controller 30 on the other hand is connected to and operable to drive the invert that includes the transistors S₁-S₄ on the primary side of the WPT system.

Due to the existence of the voltage rising time of the u_{P} and u_{S}, and the parasitic capacitance Cp of the multiturn wire, the voltage transient on the sensor inductor does not change instantaneously but has a rising or falling time as shown in FIG. 11(a). FIG. 11(b) presents a method of using the difference between the measured value and the predicted value to determine voltage transient time. Assume that the voltage change time is ΔTₜ, the predicted voltage value at the current moment (t=0) can be calculated by the data from the previous ΔTₜ (t=−ΔTₜ) to previous ΔTₜ/2 time (t=−ΔTₜ/2). The predicted voltage can be expressed as:

$${u}_{L {s}_{p r e d i c t}} ( t = 0 ) = 2 {u}_{L s} ( t = - Δ {T}_{t} / 2 ) - {u}_{L s} ( t = - Δ {T}_{t} ) \qquad ( 6 )$$

If the difference between the measured voltage and the predicted voltage is greater than the threshold, it is determined as a rising edge. If it is less than the threshold, it can be determined as a falling edge. The threshold here can be set to approximately 0.25 times

$${U}_{{L}_{2 t}}^{P}$$

shown in (2).

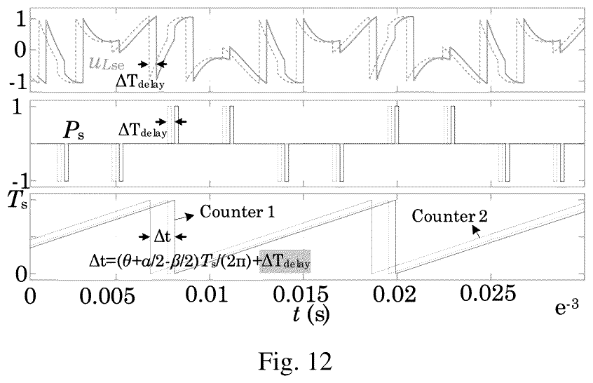

The time delay ΔT_{delay} caused by the voltage sensing and sampling circuits should also be considered, which can be measured offline during product design. FIG. 12 presents the compensation scheme, where the dotted line represents the theoretical waveform before the time delay. It can be found that counter 1 will also delay ΔT_{delay}. To have an accurate counter 2, time compensation should be applied. Compared to FIG. 8(e), the time delay ΔT_{delay} should be added to Δt. The other cases shown in FIG. 9 have similar properties.

TABLE I
Experimental Parameters of the WPT System

| Parameter | Symbol | Value | |
|---|---|---|---|
| Input voltage of the inverter | Vᵢₙ | 20 | V |
| Output voltage of the rectifier | Vₒ | 20 | V |
| Resonant Frequency of the transmitter | f₁ | ≈85 | kHz |
| Resonant Frequency of the receiver | f₂ | ≈85 | kHz |
| Self-inductance of the primary-side coil | L₁ | ≈71 | μH |
| Self-inductance of the secondary-side coil | L₂ | ≈71 | μH |

| | | |
|---|---|---|
| Coupling coefficient | k | 0.13-0.3 |

To verify the synchronization method according to the above-described embodiment, several experiments are implemented. The experimental parameters are shown in Table I. The main controller is FPGA EP4CE10. The magnetic ring uses a nickel-zinc ferrite magnetic ring with a magnetic permeability of 100, and the turn of the wire on the ring is 22. After inserting the magnetic core, the Lₛ tested to about 70 nH, which means the power loss on the magnetic ring can be ignored. The AD sampling chip is AD9226, which supports a maximum sampling rate of 65 MHz. The sampling frequency used in the experiment is 50 MHz (20 MHz is also feasible). As long as the transient of u_{Lse} can be extracted, the sampling frequency can be lowered. However, it is not recommended to use a sampling frequency lower than 10 MHz). The center frequency of the notch filter is 85 kHz, and the −3 db bandwidth is 70 kHz. Since the load voltage will not affect

$${U}_{{L}_{S}}^{P} ,$$

load will not affect the synchronization, considering page limit, only 20 V is presented.

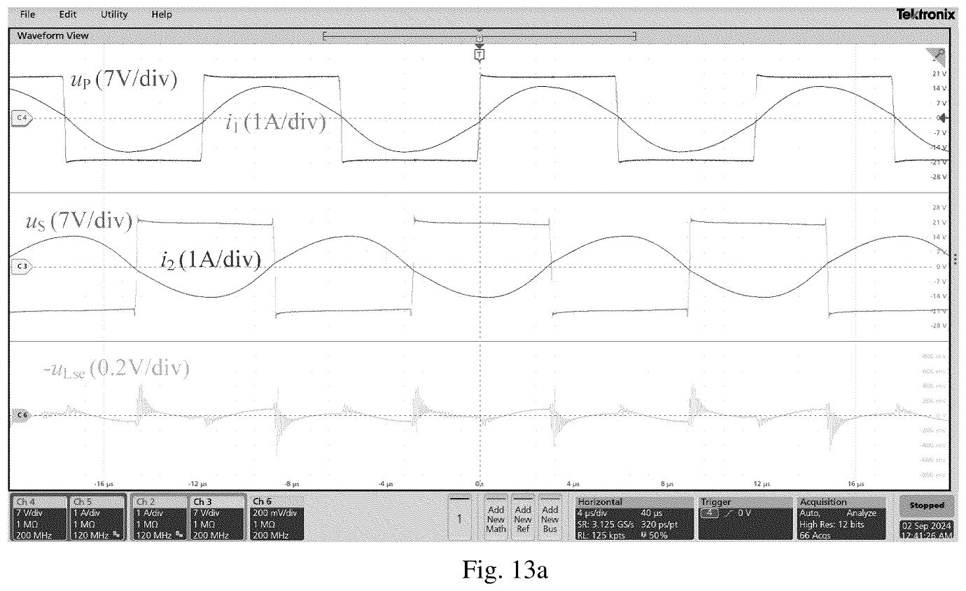

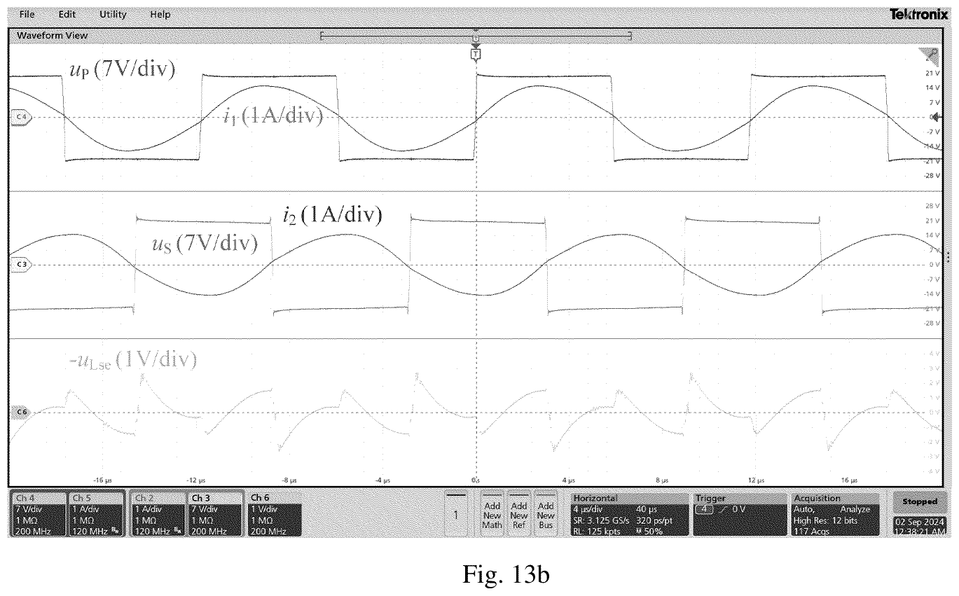

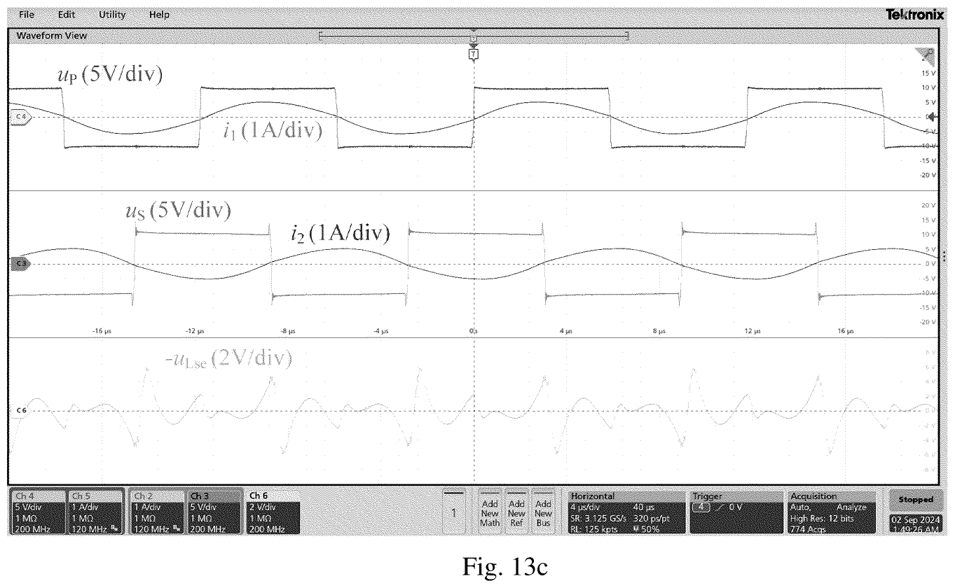

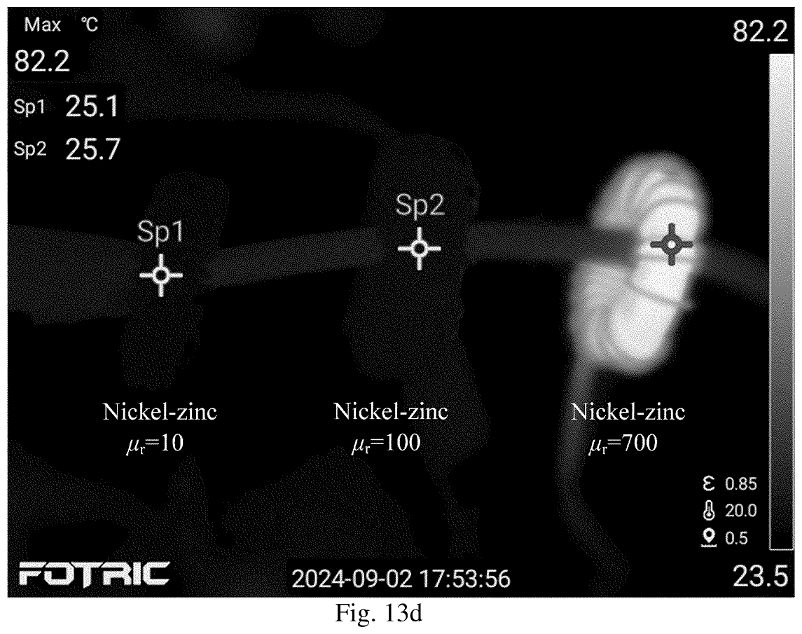

FIGS. 13a, 13b, 13c and 13d show the voltage waveform u_{Lse} on the magnetic ring with different permeability values μᵣ. It can be observed that when μᵣ=10, the voltage on u_{Lse} is very small and almost buried in noise, making it difficult to accurately detect the transient point. When μᵣ=100, as shown in FIG. 13b, the waveform quality is significantly improved, and the transient feature is clear. However, in FIG. 13c, when μᵣ=700, as the magnetic core tends to be saturated, and the waveform is distorted. Furthermore, by adjusting the input voltage to make the amplitude of i₁ equal to 4 A and operating for 10 min, it is found that the temperature of the magnetic ring with μᵣ=700 reaches as high as 82° C. In contrast, the temperatures of the magnetic rings with μᵣ=10 and 100 are only 25-26° C. Considering the effect of permeability on the voltage waveform and the loss on the magnetic ring, the magnetic ring with μᵣ=100 is chosen for the experiment. Of course, if the overall magnetic permeability is reduced by increasing the air gap, manganese-zinc ferrite can also be used as the ring.

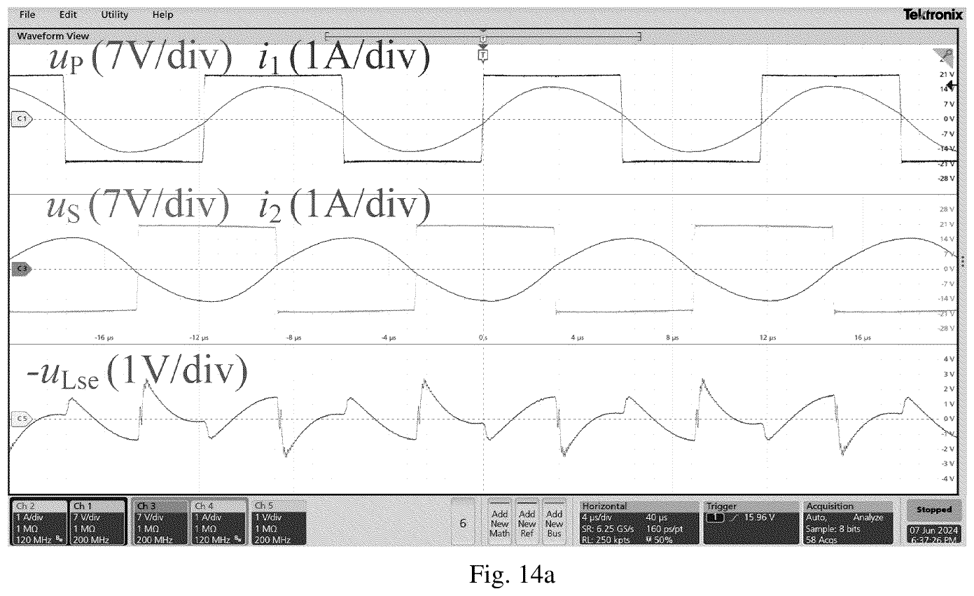

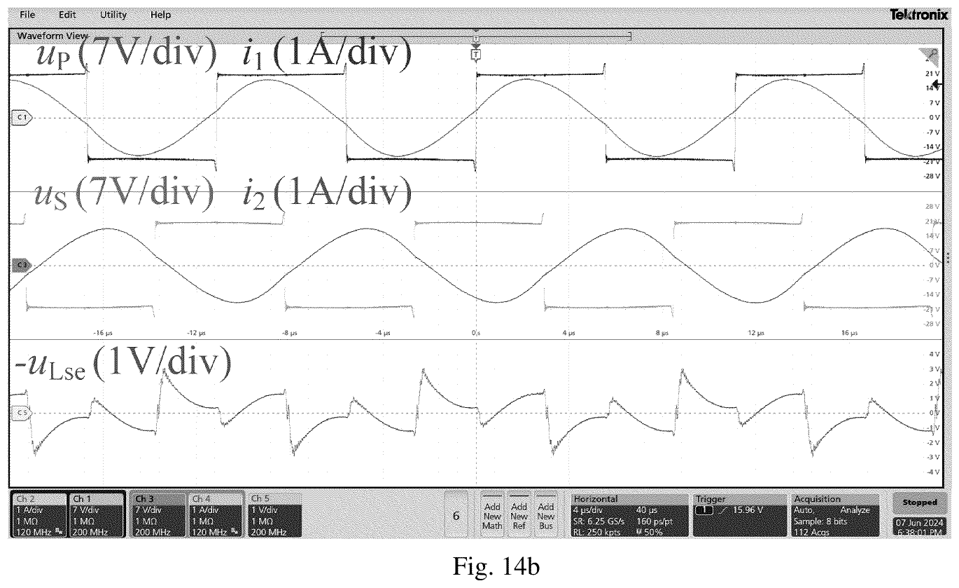

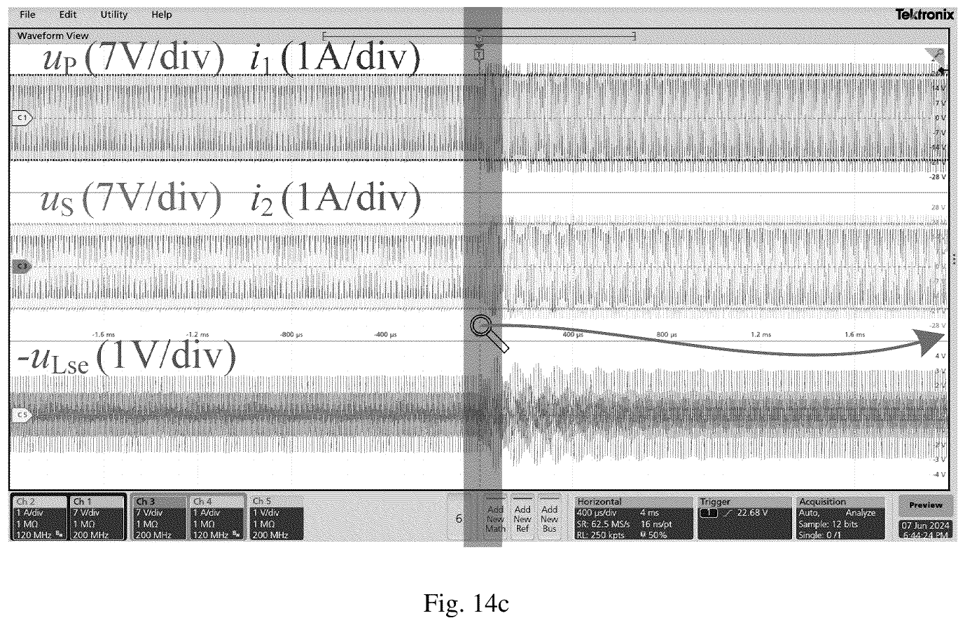

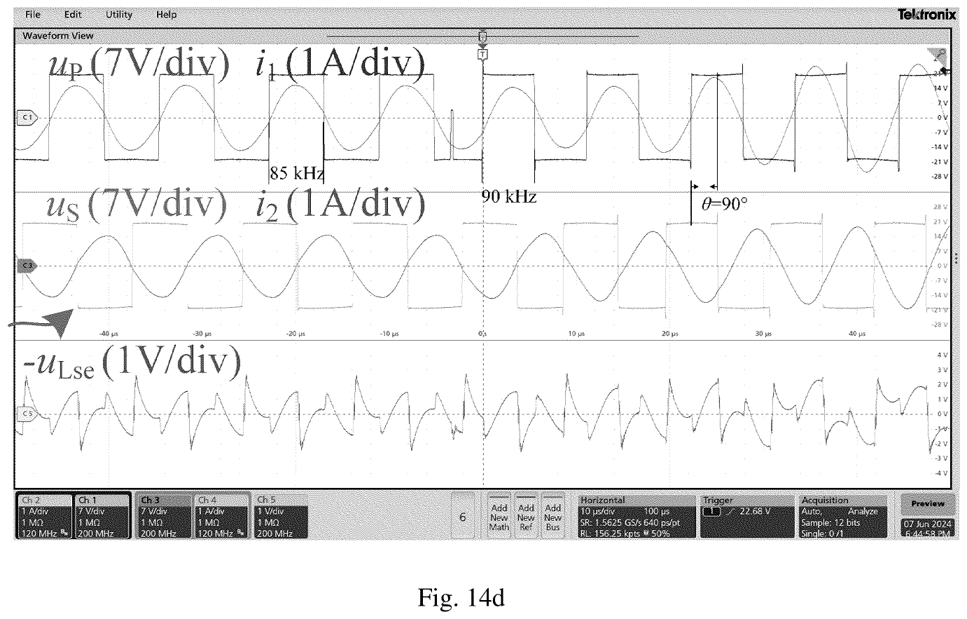

High efficiency and ZVS can be achieved by controlling the angle between u_{P} and u_{S} to 90° and no phase shift on both sides [3]. In FIG. 14a, the most common case (α=β=180°, θ=90°) is presented. By using the proposed synchronization method, the angle between u_{P} and u_{S} can be stabilized at 90° whether at the system resonant frequency (85 kHz) or the detuned frequency (90 kHz). The dynamic waveforms shown in FIG. 14c and FIG. 14d present that the synchronization method can be completed within one switching cycle, regardless of whether the system current is stable or not.

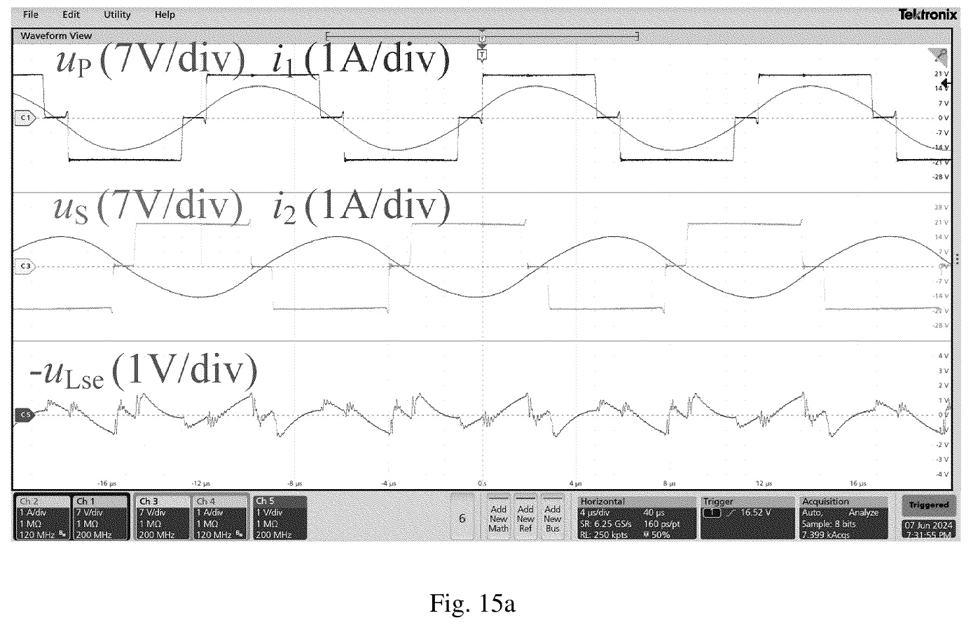

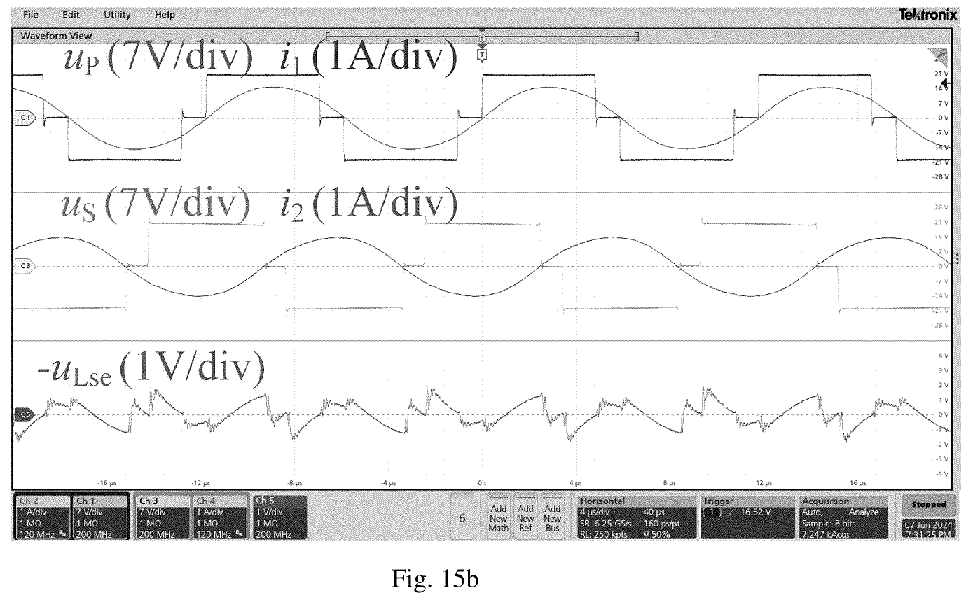

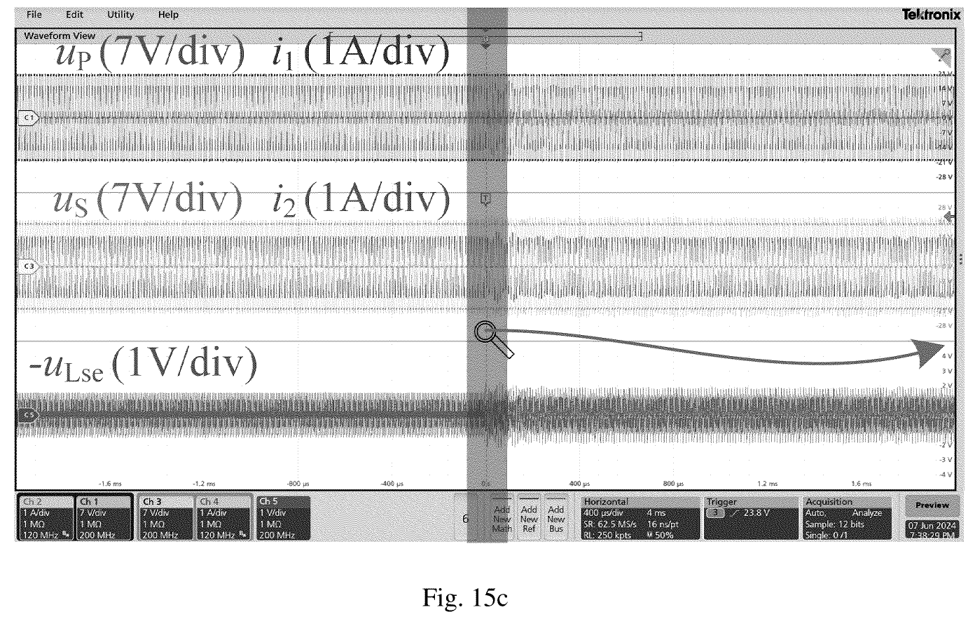

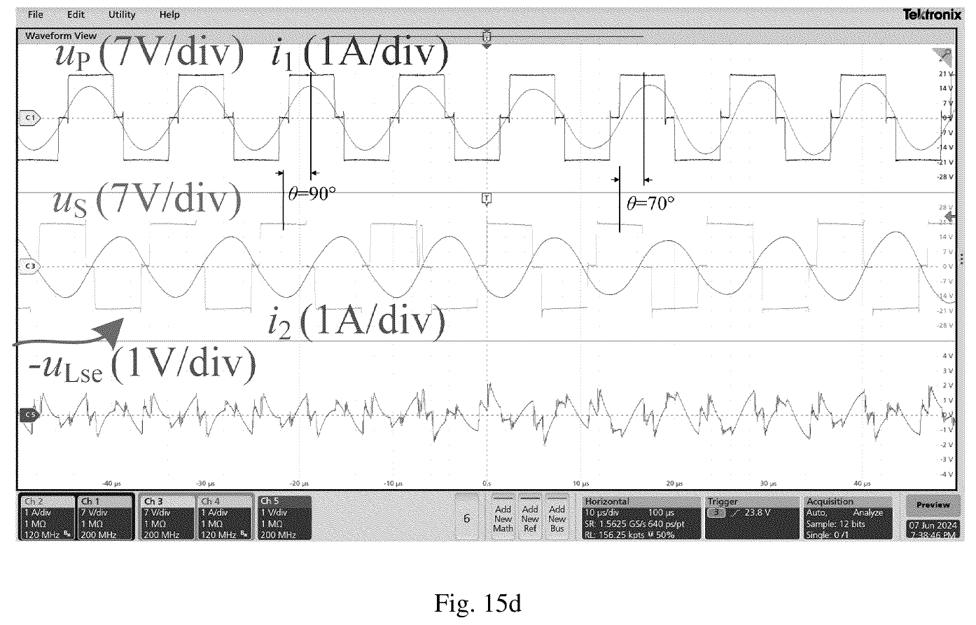

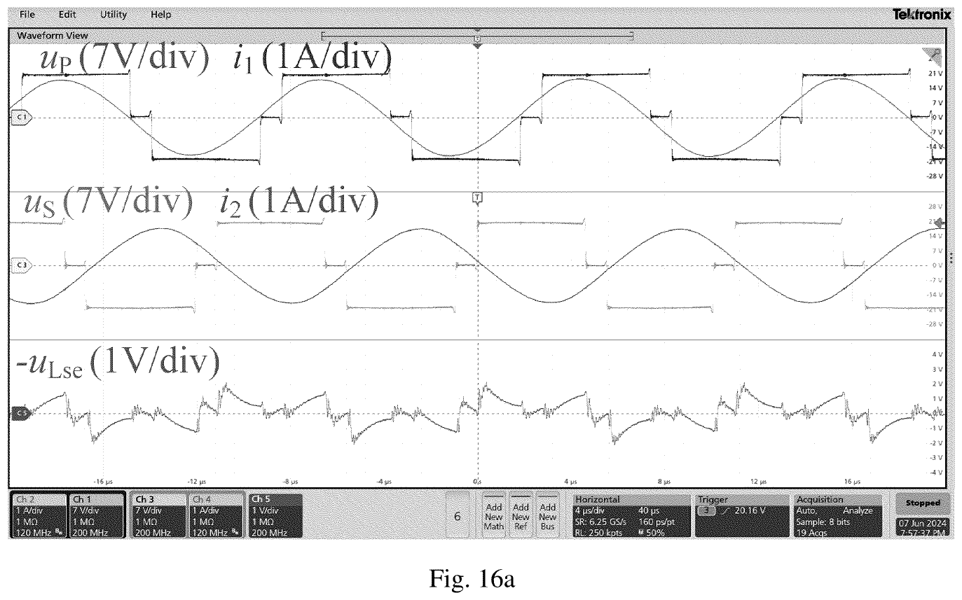

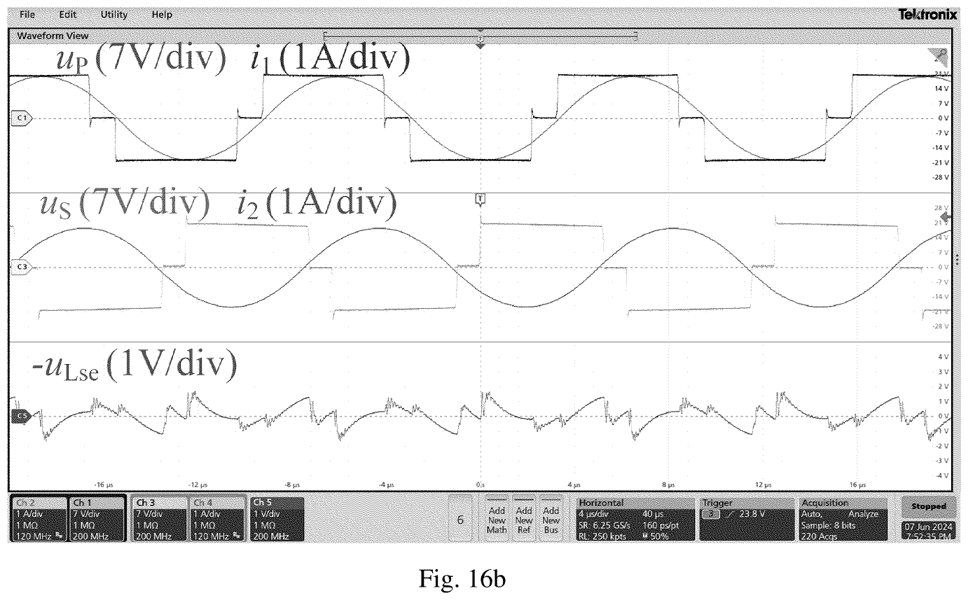

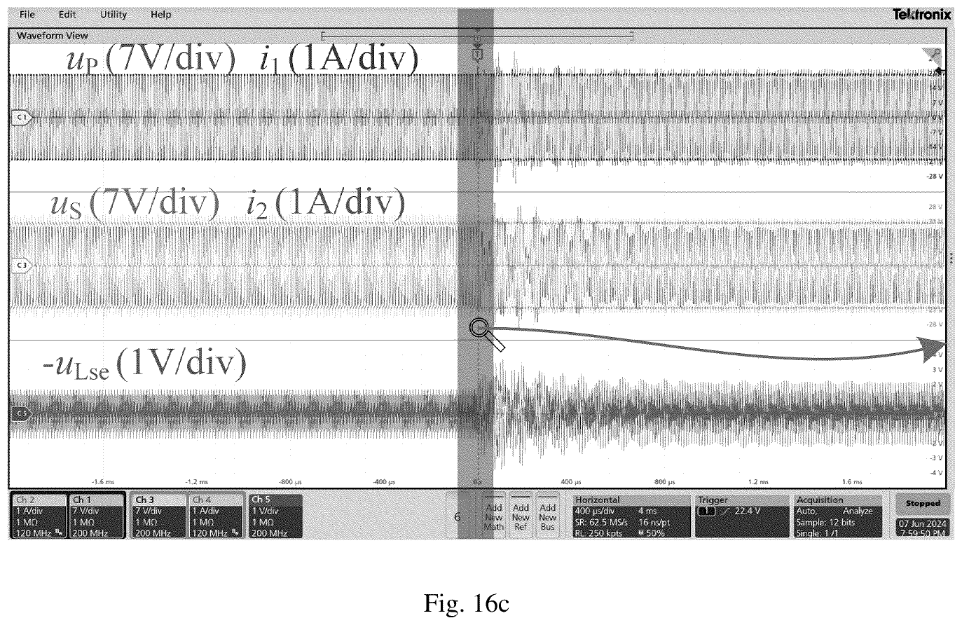

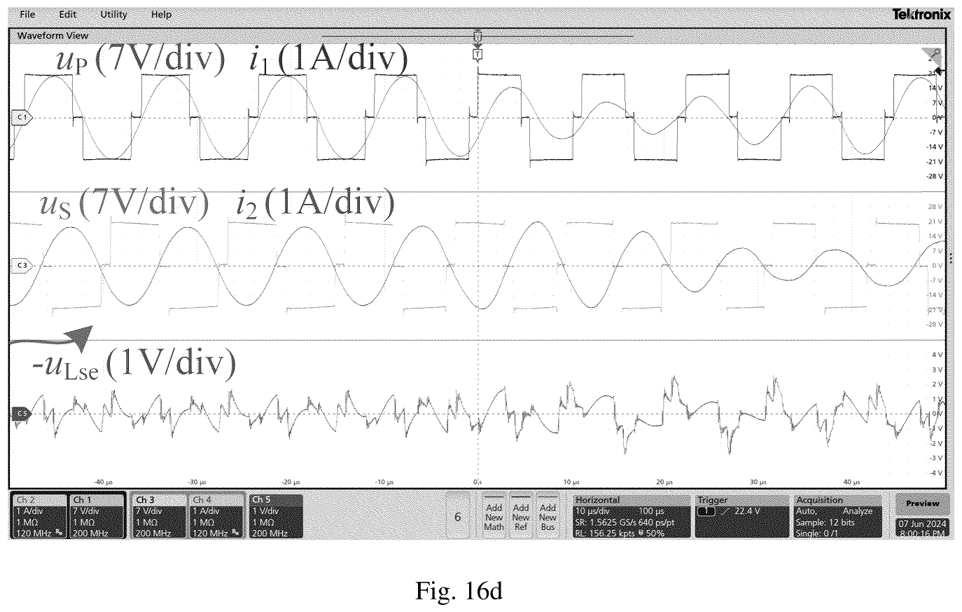

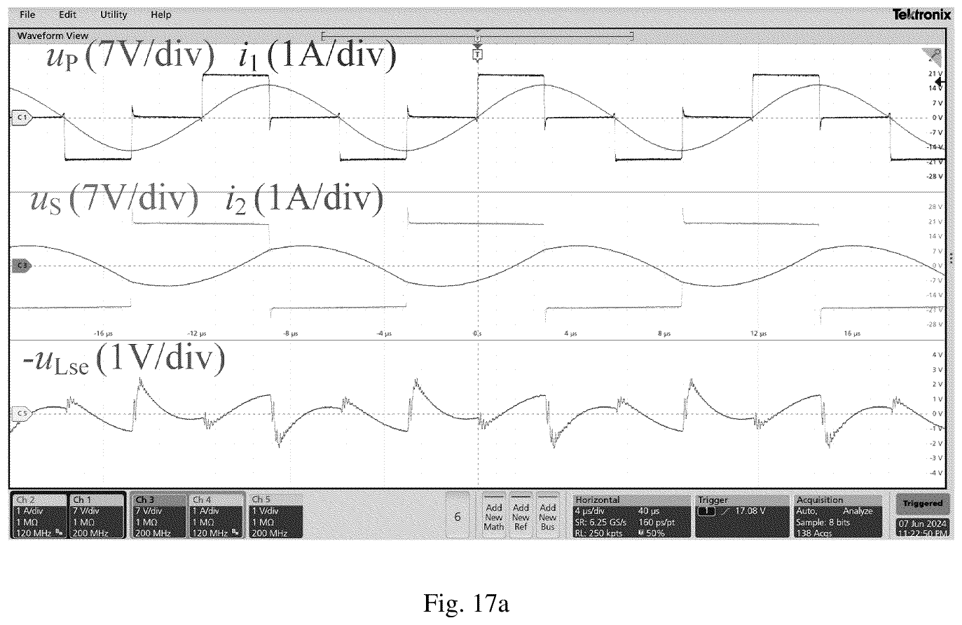

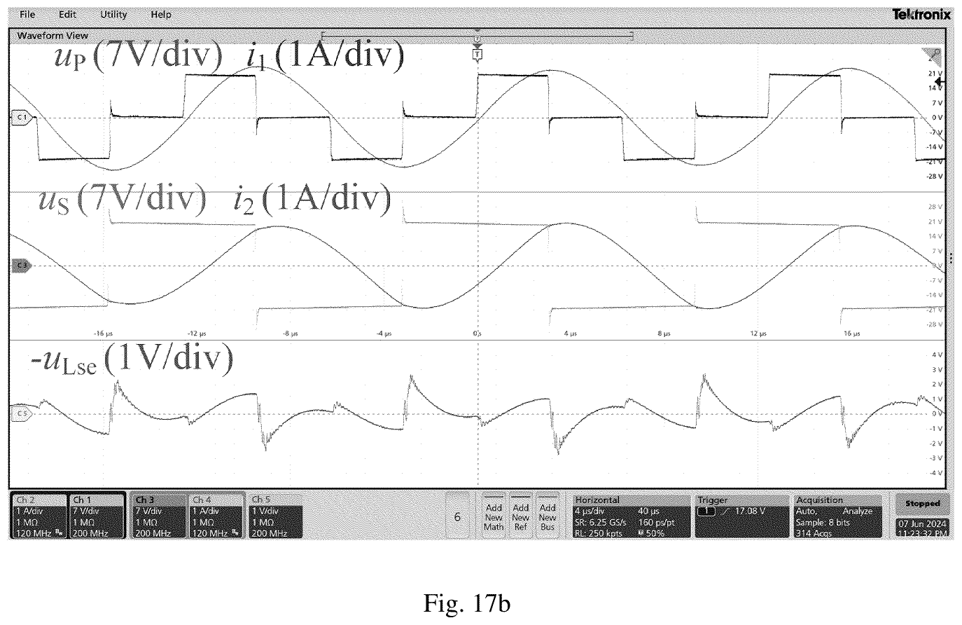

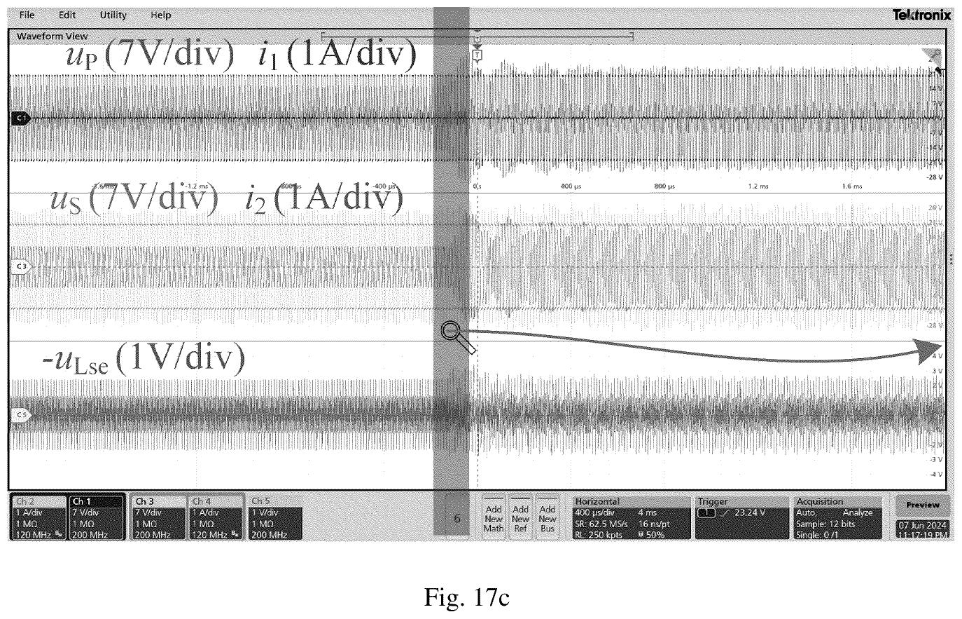

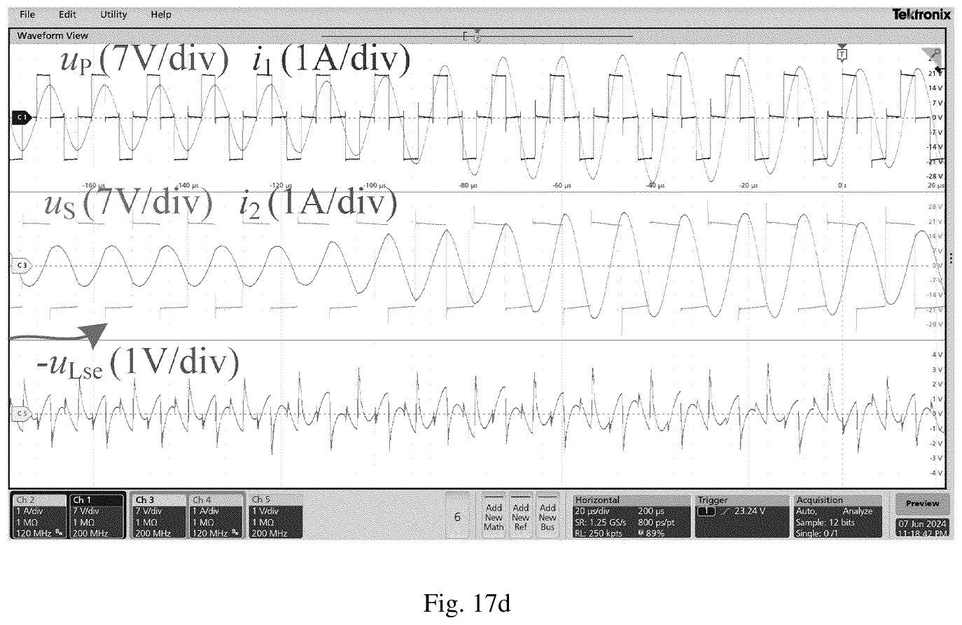

In FIGS. 15a, 15b, 15c and 15d, the TPS case is implemented to verify the method shown in FIG. 8. It can be found that the synchronization can be achieved very well whether θ is 90° or 70°. During the transition process of θ change, synchronization can be completed quickly without the need for the system to run to a stable state (less than two switching periods). Similarly, as shown in FIGS. 16a, 16b, 16c and 16d, when the operating frequency changes from 90 to 80 kHz, the synchronization can also be quickly completed, which presents that the method has the advantages of resisting system detuning and fast synchronization.

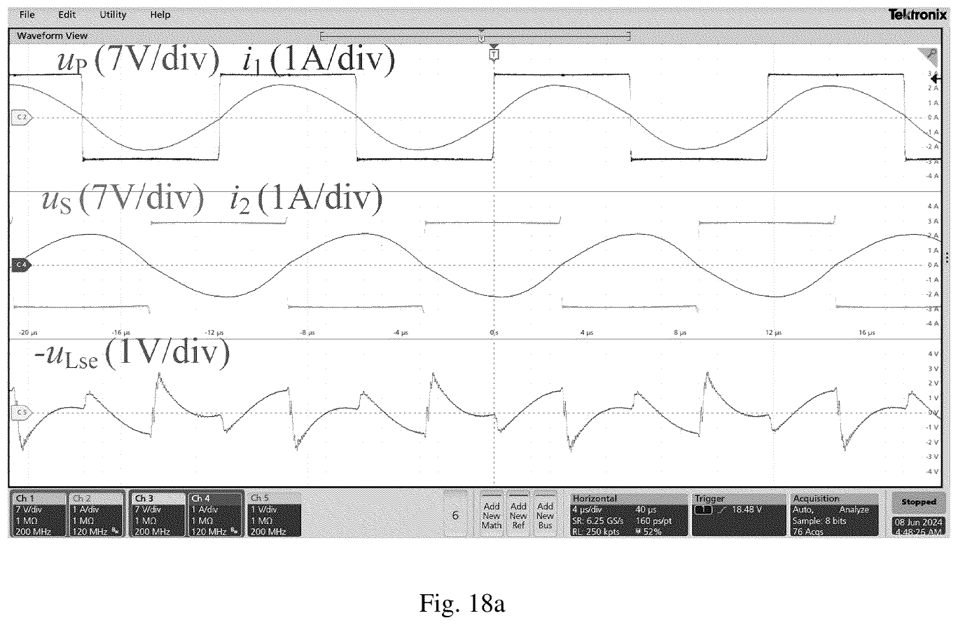

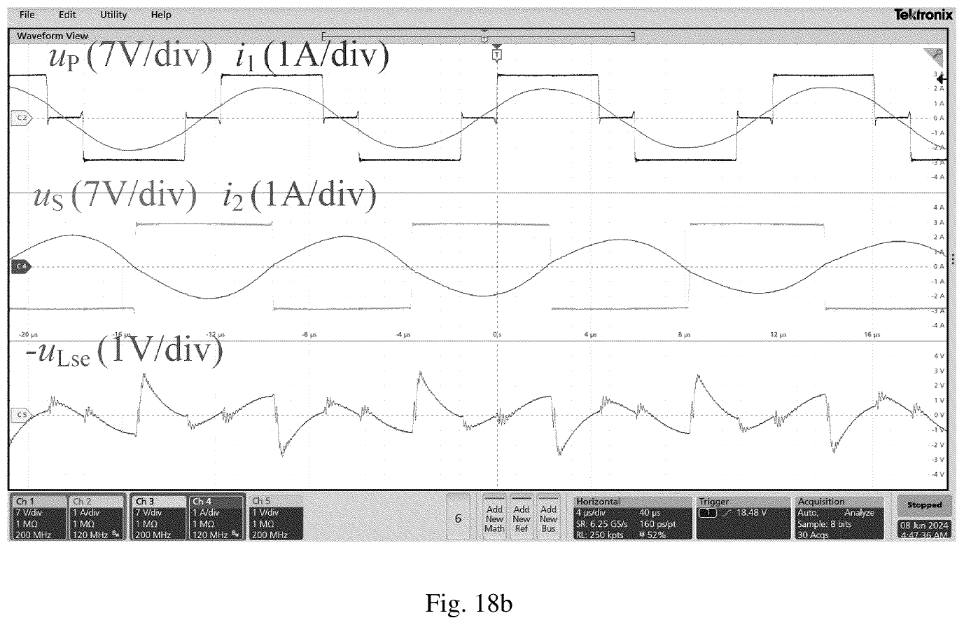

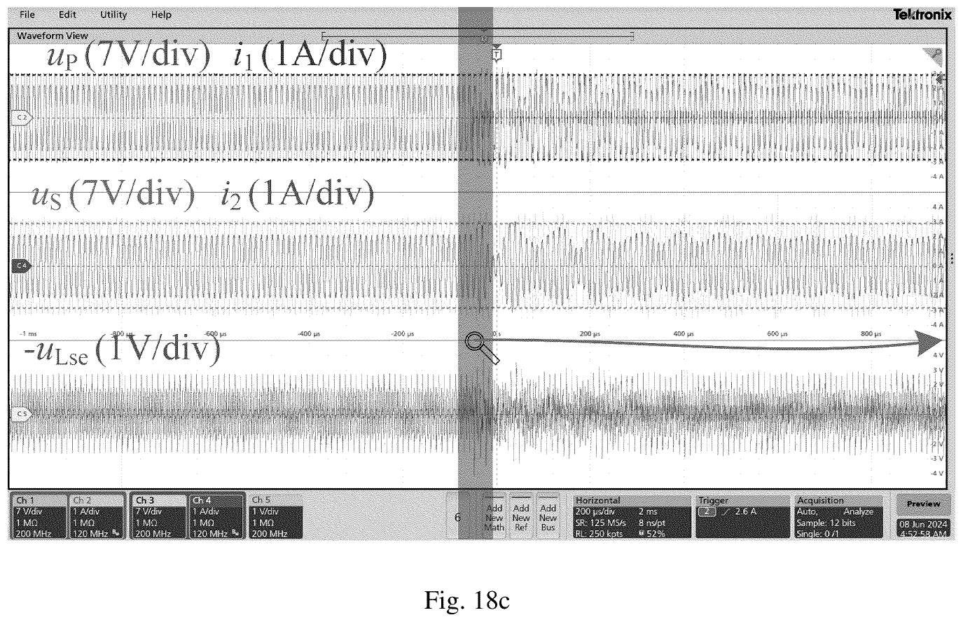

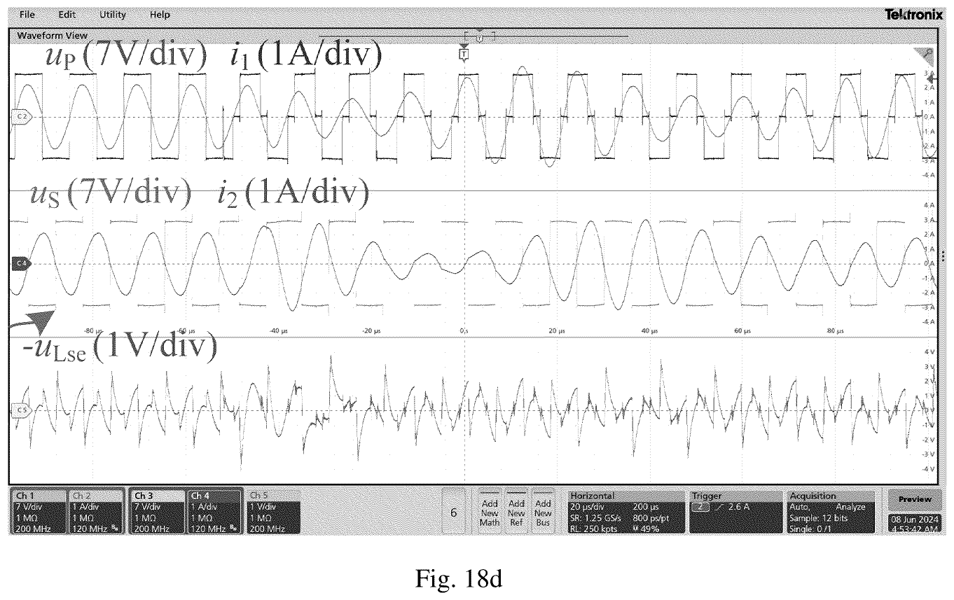

As shown in FIG. 9, it may happen that the transient points of u_{P} and u_{S} overlap. Since these processing methods are similar, only one situation is shown here as presented in FIGS. 18a, 18b, 18c and 18d. The performance is also satisfactory, with fast synchronization when the operating frequency changes from 85 to 80 kHz.

When a changes suddenly, as presented by the theory analysis shown in FIG. 8, the phase shift angle of u_{P} can be sensed by the secondary side by detecting the time of adjacent falling edge and rising edge on u_{Lse} at the secondary side. Consequently, when θ and β remain unchanged, synchronization can be completed no matter how a changes. As shown in FIGS. 18a, 18b, 18c and 18d, when a changes from 1800 to 135°, the phase difference θ can be kept at 90°. Similarly, the synchronization can be completed quickly.

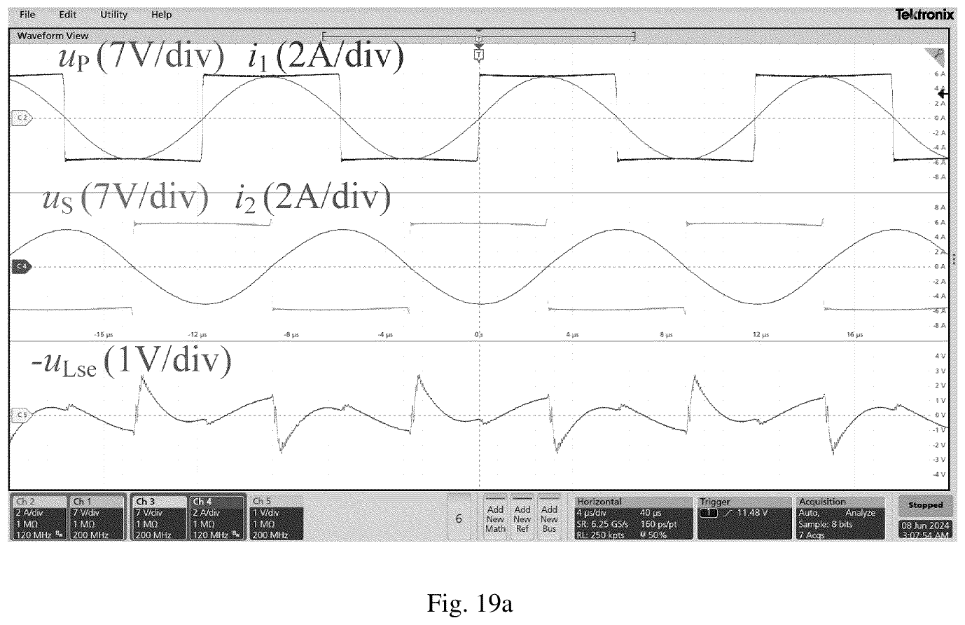

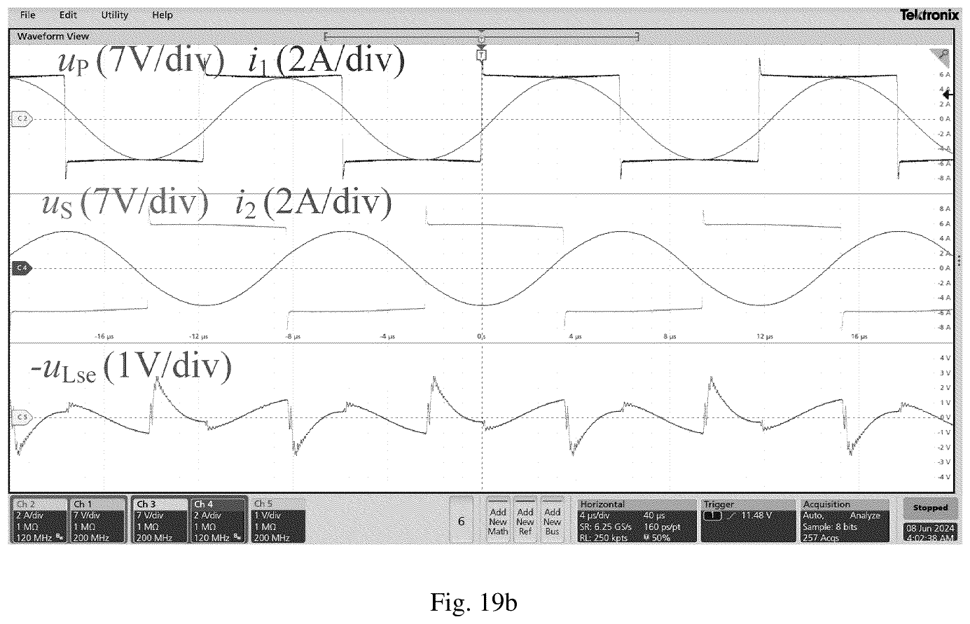

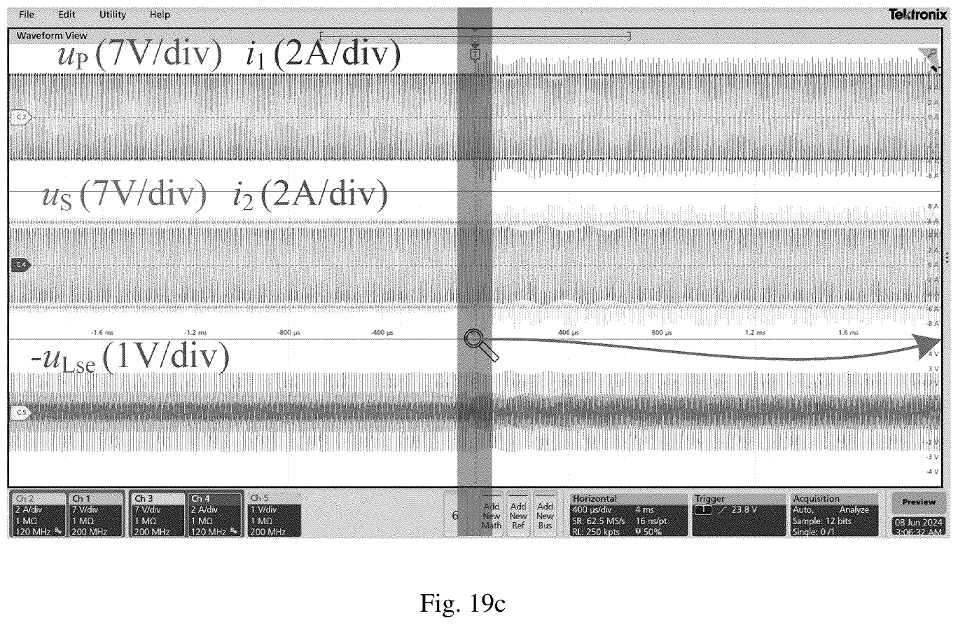

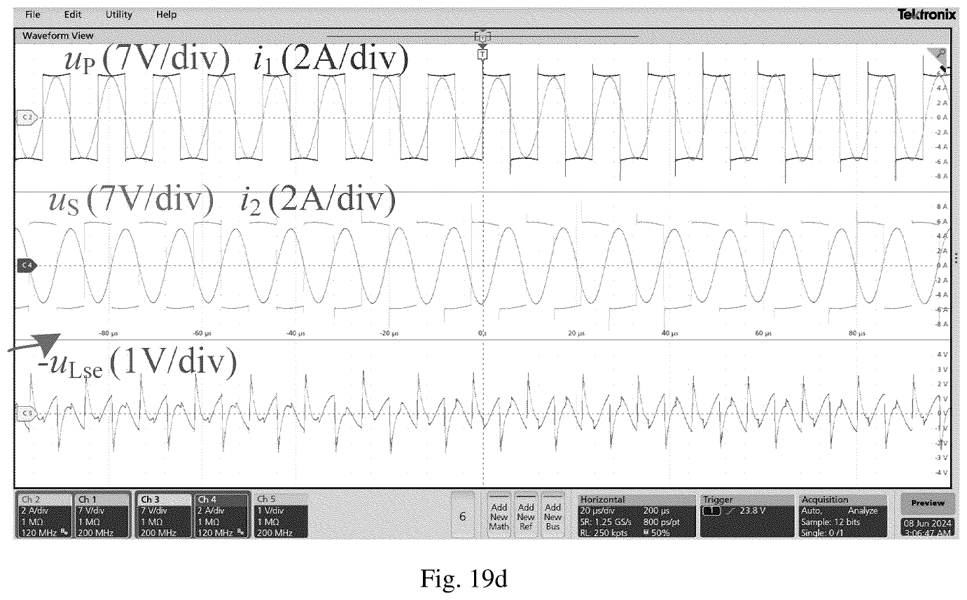

When the coil's misalignment distance is 8 cm, the coupling coefficient decreases to 0.13. According to the analysis in FIG. 4, the voltage transient amplitude caused by u_{P} will be affected. It means that the transient detection will be difficult. The voltage of the small inductor requires a good signal ratio. However, if k is not particularly small, the transient phenomenon is still easy to detect accurately. FIGS. 19a, 19b, 19c and 19d present the experimental results when k decreases to 0.13. The synchronization can also have a satisfactory performance. For the case of the multiphase shift when k is very small, in terms of hardware design, the signal-to-noise ratio and sampling accuracy need to be fully guaranteed to achieve stable synchronization. If the signal-to-noise ratio is not controlled very well, it is not recommended to apply this method to TPS control at very loose coupling, but the most classic modulation [3] without additional phase shifts on both sides is easy to achieve stably. In addition, when the period or phase shift angle changes of u_{P} are detected multiple times during a continuous time, adjusting the switching action of the receiver can also reduce the impact of voltage transient misjudgment on synchronization.

As discussed previously, the ZCD-based synchronization scheme for WPT systems has limitations due to its susceptibility to harmonic interference and system detuning, which has led to the development of more complex schemes, including methods that detect and process the secondary-side resonant coil current. These strategies typically rely on the assumption that the fundamental component of the resonant inductor current at the receiver side lags the fundamental component of the excitation voltage at the transmitter side by 90°. However, this assumption will be affected during system detuning, rendering these schemes defective in scenarios such as frequency control. Moreover, these schemes often require PI controllers, resulting in synchronization times of several milliseconds or more.

In contrast, the synchronization method described in the above exemplary embodiment achieves rapid synchronization of u_{P} and u_{S} within one or two switching cycles (<25 μs). Table II provides a comparison of the proposed scheme with existing methods in terms of computational complexity and hardware requirements. The proposed method requires only a magnetic ring to achieve synchronization at any phase difference between u_{P} and u_{S}, without complex calculations or control.

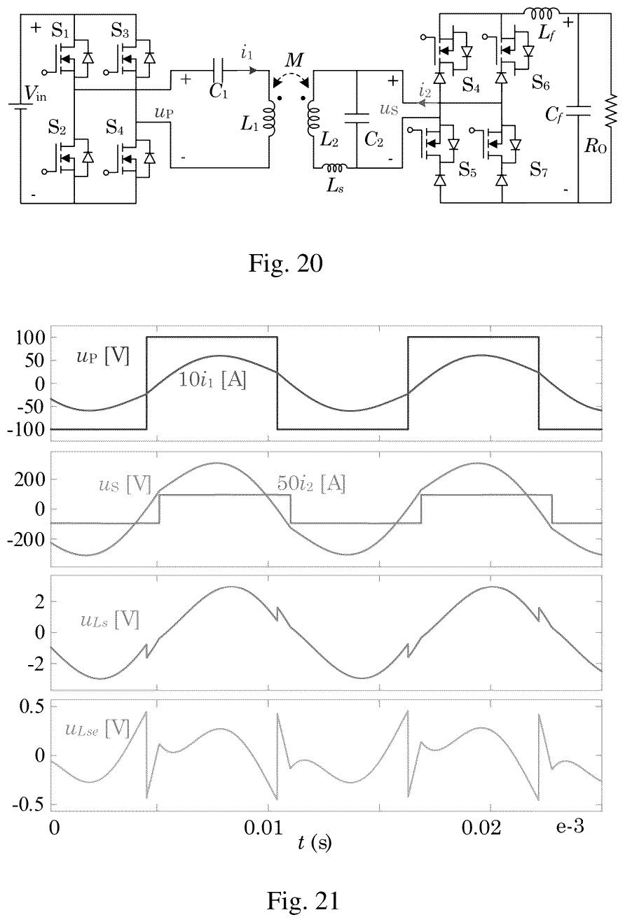

Although the theoretical analysis and experimental verification demonstrate the effectiveness of the proposed method in SS-compensated WPT systems, it can also be applied to the SP-compensated WPT system. An example of the SP compensation structure is illustrated in FIG. 20, where the equivalent sensor inductor Lₛ is connected in series with the receiving coil. FIG. 21 depicts the voltage waveform on Lₛ and after the notch filter. When the voltage u_{P} rises or falls, a corresponding voltage transient occurs on Lₛ. However, due to the parallel structure of the secondary side, the voltage across capacitor C₂ does not have a transient phenomenon, as charging and discharging require time. Consequently, during the switching action of the receiving side, despite the sudden change in i₂, the voltage u_{Ls} remains unchanged due to the absence of a sudden change in the voltage across C₂. Since the switching state of u_{S} is known to the controller on the receiving side, only the rising and falling states of u_{P} need to be detected to achieve synchronization between the two sides. The synchronization is consistent with the SS-compensated WPT systems.

TABLE II
Comparison of different methods

| | | | | | System | |
|---|---|---|---|---|---|---|
| | Synchronous | | Computational | | Detuning | |
| Methods | Time | | Complexity | Additional Hardware | Effect | Main Disadvantage |
| [8] | <1000 | ms | Medium | Current sensor, wireless | Yes | Cannot achieve arbitrary |
| | | | | communication | | phase differences |
| [9]-[13] | / | | Low | Current sensor | Yes | Harmonic and system |
| | | | | | | detuning will affect the |
| | | | | | | synchronization |
| [15] | <2 | ms | High | Current sensor | Yes | System detuning will |
| | | | | | | affect synchronization |
| [16] | <2 | ms | High | Voltage sensor, current sensor | Yes | System detuning will |
| | | | | | | affect synchronization |
| [18] | / | | High | Voltage sensor, current sensor | Yes | Harmonic and system |
| | | | | | | detuning will |
| | | | | | | affect synchronization |
| [21] | / | | Low | Auxiliary coil, additional | No | The auxiliary coil is too |
| | | | | inverter, | | large |
| | | | | current sensor | | |
| This | <25 | μs | Low | Magnetic ring | No | / |

work

In summary, one can see the exemplary embodiments described above provide synchronization methods based on voltage transient detection. The sensor inductor (for example a magnetic ring with multiple turns of a wire) connected in series with the resonant tank at the secondary side is used to detect the voltage transient of the inverter, and then the notch filter is used to enhance the transient feature. The synchronization method can further realize the synchronous operation of the inverter and rectifier by using the detected voltage transient information on the sensor inductor. The experimental results present that the method can be applied to the multiphase shift operation, and not affected by the system detuning. Only a magnetic ring, a sampling module, and a signal conditioning circuit are needed to achieve synchronization, and the calculation is extremely simple, making it very suitable for practical applications.

In another aspect, embodiments of the invention introduce a synchronization method for WPT systems which utilize an equivalent sensor inductor, implemented for example as a magnetic ring with multiple coil turns, connected in series to the resonant tank on the secondary (receiver) side. This sensor inductor is pivotal for detecting voltage transients caused by sudden changes in the inverter's output voltage. The method employs a notch filter to accentuate the transient features detected by the sensor inductor. By analyzing these voltage transients, the system can achieve frequency and phase synchronization between the inverter and rectifier, ensuring that both sides operate in harmony. This synchronization process is robust against system detuning and is adaptable to various operating frequencies, making it highly versatile. Experimentally, this method has been successfully tested with triple-phase shift control and has shown potential applicability to broader multiphase shift control configurations. The simplicity of the required components—a magnetic ring, a sampling module, and a signal conditioning circuit—combined with minimal computational demands, makes this method particularly practical for real-world implementation.

The main functions of the invention described in the synchronization method for WPT systems are as follows:
1. Phase and Frequency Synchronization: By analyzing the detected voltage transients, the method synchronizes the frequency and phase between the inverter and the rectifier. This ensures that both sides of the WPT system operate in harmony, optimizing power transfer efficiency.
2. Robustness Against Detuning: The synchronization process is designed to be robust against system detuning, which can occur due to variations in operating conditions or physical displacements in the system components. This feature enhances the reliability and effectiveness of the WPT system across different scenarios.
3. Simplicity and Low Computational Requirement: The method relies on simple components like a magnetic ring, a sampling module, and a signal conditioning circuit. It does not require complex computations, making it easy to implement and maintain.

The applications of the invention described in the synchronization method for WPT systems are as follows:
1. Consumer Electronics Charging: The method can be applied to the charging systems of smartphones, laptops, tablets, and other consumer electronics, where efficient, reliable wireless charging is highly desirable.
2. Electric Vehicle Charging: This synchronization method can be particularly beneficial in wireless charging systems for electric vehicles, including both stationary charging stations and dynamic charging scenarios.
3. Medical Implants and Devices: The method could be adapted for use in medical technology, particularly for charging or powering implants and medical devices wirelessly, which requires highly reliable and safe power delivery.

The system is advantageous over existing technology/products as follows.
1. Robustness Against System Detuning: Adaptability to Variations: The synchronization approach is not affected by system detuning caused by variable operational conditions or physical displacement of components.
2. Simplicity and Cost-Effectiveness: Minimal Component Requirement: The system requires only a few simple components such as a magnetic ring, a sampling module, and a signal conditioning circuit. This simplicity reduces the cost and complexity of the system, making it more accessible and easier to maintain.
3. Low Computational Load: Unlike some existing technologies that rely on heavy computational algorithms for synchronization and control, this method uses straightforward signal processing, which can be implemented with less computation.

The exemplary embodiments are thus fully described. Although the description referred to particular embodiments, it will be clear to one skilled in the art that the invention may be practiced with variation of these specific details. Hence this invention should not be construed as limited to the embodiments set forth herein.

While the embodiments have been illustrated and described in detail in the drawings and foregoing description, the same is to be considered as illustrative and not restrictive in character, it being understood that only exemplary embodiments have been shown and described and do not limit the scope of the invention in any manner. It can be appreciated that any of the features described herein may be used with any embodiment. The illustrative embodiments are not exclusive of each other or of other embodiments not recited herein. Accordingly, the invention also provides embodiments that comprise combinations of one or more of the illustrative embodiments described above. Modifications and variations of the invention as herein set forth can be made without departing from the spirit and scope thereof, and, therefore, only such limitations should be imposed as are indicated by the appended claims.

For example, although in the experimental setup as mentioned above, the prototype of the wireless power transfer system is built with a magnetic ring, those skilled in the art should understand that the magnetic ring is not the only way to implement the invention. Instead, other types of sensor inductor may also be used. In other words, while an equivalent small sensor inductor can be connected in series in the resonant tank, inserting a magnetic ring is only one way of implementing the sensor inductor. Other methods and structures such as directly connecting an inductor in series in the resonant cavity and directly sampling and processing the voltage on the inductor also can be used to implement the WPT system and which are within the scope of the invention.

For the magnetic ring configuration, the exemplary embodiment above uses a nickel-zinc ferrite magnetic ring with a magnetic permeability of 100, but those skilled in the art will understand that the invention is not limited to any particular composition of the material for the magnetic ring or value of the magnetic permeability. For example, other magnetic materials besides nickel-zinc ferrite are permissible, provided that their permeability meets the requirements and the core is not saturated, allowing for the extraction of transient characteristics. The number of turns on the magnetic ring is also not fixed, and can be adjusted. Moreover, in variations of the embodiments, the value of the magnetic permeability could also be adjusted according to practical needs, for example in the range from tens to hundreds.

Additionally, although a notch filter is configured in the exemplary embodiment of the WPT system as described above, those skilled in the art should realize that both notch filters and high-pass filters can be utilized in other variations of the embodiments, as long as they can facilitate effectively detecting voltage transients.

What is claimed is:

1. A wireless power transfer (WPT) system with a series compensation structure on a primary side, the system comprising:
a) an inverter at the primary side;
b) a rectifier at a secondary side;
c) a resonant circuit configured between the inverter and the rectifier; the resonant circuit comprising a primary coil and a secondary coil;
wherein the resonant circuit further comprises a sensor inductor connected to the secondary coil; the sensor inductor adapted to detect voltage transients on the sensor inductor.

2. The WPT system of claim 1, wherein the sensor inductor is connected to the secondary coil in series.

3. The WPT system of claim 2, wherein the sensor inductor is connected to a different terminal of the secondary coil than a capacitor at the secondary side which is also connected to the secondary coil.

4. The WPT system of claim 1, wherein the sensor inductor comprises a magnetic ring.

5. The WPT system of claim 4, wherein the magnetic ring is wound with a multiturn coil.

6. The WPT system of claim 4, wherein the magnetic ring is a nickel-zinc magnetic ring.

7. The WPT system of claim 4, wherein the magnetic ring has a magnetic permeability of 100.

8. The WPT system of claim 4, wherein the magnetic ring has a number of coil turns equal to 22.

9. The WPT system of claim 1, wherein the rectifier is an active rectifier comprising a plurality of transistors; the sensor inductor being further coupled with a sampling circuit, which in turn connects to a driving circuit; the driving circuit adapted to provide driving signals to the rectifier based on the detected voltage transients by the sensor inductor.

10. The WPT system of claim 8, wherein the sensor inductor is connected to a filter, which in turn connects to the sampling circuit.

11. The WPT system of claim 9, wherein the filter is a notch filter or a high-pass filter.

12. A method for phase synchronization between a primary side and a secondary side of a wireless power transfer (WPT) system with a series compensation structure, the WPT system comprising an inverter at the primary side and an active rectifier at the secondary side; the method comprising:
a) detecting, at the secondary side, voltage transients by a sensor inductor;
b) sampling the detected voltage transients; and
c) controlling an operation of the active rectifier based on the detected voltage transients.

13. The method of claim 11, further comprises a step of filtering the detected voltage transients from the sensor inductor by a filter.

14. The method of claim 12, wherein the filter is a notch filter or a high-pass filter.

15. The method of claim 11, wherein the sensor inductor comprises a magnetic ring.

16. The method of claim 14, wherein the magnetic ring is wound with a multiturn coil.

17. The method of claim 14, wherein the magnetic ring is a nickel-zinc magnetic ring.

18. The method of claim 14, wherein the magnetic ring has a magnetic permeability of 100.
